(19) United States
(12) Patent Application Publication
(10) Pub. No.: US 2024/0391836 A1
(43) Pub. Date: Nov. 28, 2024

(54) UV-ACTIVATED RED CERAMIC BODIES COMPRISING YAG FOR USE IN SEMICONDUCTOR PROCESSING CHAMBERS

(71) Applicant: Heraeus Conamic North America LLC, Chandler, AZ (US)

(72) Inventors: Luke WALKER, Chandler, AZ (US); Matthew Joseph DONELON, Chandler, AZ (US); Steven Roger KENNEDY, Chandler, AZ (US)

(21) Appl. No.: 18/689,324

(22) PCT Filed: Sep. 2, 2022
(86) PCT No.: PCT/US2022/075897

§ 371 Date: Mar. 5, 2024

Related U.S. Application Data
(60) Provisional application No. 63/242,631, filed on Sep. 10, 2021.

(51) Int. Cl. C04B 35/44; C04B 35/626; C04B 41/00; C04B 41/91

(52) U.S. Cl. CPC C04B 35/44; C04B 35/6268; C04B 41/0045; C04B 41/0081; C04B 41/91; C04B 2235/3217; C04B 2235/3222; C04B 2235/3225; C04B 2235/5409

(57) ABSTRACT

A sintered ceramic body comprising at least one layer comprising from 90% to 99.8% by volume of polycrystalline yttrium aluminum garnet (YAG) and from 15 ppm to 500 ppm of zirconium, wherein the at least one layer comprises at least one surface, wherein the at least one surface comprises pores having a pore size not exceeding 5 pm and having a maximum pore size of 1.5 pm for at least 95% of the pores, wherein the at least one surface exhibits an L* value of from 50 to 77, and an “a” value of from 6 to 12, wherein the at least one layer has a thickness of from 500 pm to 2 cm, and wherein the values of L* and “a” vary no more than 10% across the at least one surface. Also disclosed are methods of making same.

### TECHNICAL FIELD

The disclosure relates to corrosion-resistant, sintered ceramic bodies and components formed therefrom, a method of producing the ceramics, and use within semiconductor plasma processing chambers. The sintered ceramic bodies exhibit a color defined in part by an L* value of from 50 to 77.

### BACKGROUND

Semiconductor processing requires the use of halogen-based gases as well as oxygen and other gases in combination with high electric and magnetic fields to create a plasma etch environment. This plasma etch environment is made within vacuum chambers for etching materials on semiconductor substrates. The harsh plasma etch environment necessitates the use of highly corrosion resistant materials for chamber components. These chambers include component parts such as disks or windows, liners, gas injectors, rings, and cylinders that confine the plasma over the wafer being processed. These components have been formed from materials that provide resistance to corrosion and erosion in plasma environments and have been described, for example, in U.S. Pat. Nos. 5,798,016, 5,911,852, 6,123,791 and 6,352,611. However, these parts used in plasma processing chambers are continuously attacked by the plasma and, consequently, corrode, erode and roughen on the surfaces of the chamber parts that are exposed to the plasma. This corrosion and erosion contribute to wafer level contamination through the release of particles from the component surface into the chamber, resulting in semiconductor device yield loss.

Rare earth oxides, and among those in particular yttria alumina garnet YAG (Y₃Al₅O₁₂, cubic phase) and the family of related yttrium aluminum oxides such as YAP (AlYO₃) and YAM (Y₄Al₂O₉) are known to have a wide range of technological and industrial applications. YAG having a cubic, crystallographic phase has received much attention due to applications such as host materials for solid-state lasers, transparent armors, ballistic infrared window materials and its combination of mechanical, thermal and optical features. For laser applications in particular, single crystal YAG is an ideal substrate for its ability to host rare earth dopants, thus much effort has been expended to fabricate single crystal YAG. In addition to optical applications YAG is also known to be very chemically inert and exhibit high halogen-based plasma corrosion and erosion resistance.

YAG based ceramics are challenging to sinter to high densities required for advanced applications that need minimal residual porosity in the final part. For semiconductor applications involving plasma corrosion, porosity accelerates chemical attack on the surface of chamber components and can generate particles as the surface degrades with extended usage. In addition to reduced chemical resistance excessive porosity can have detrimental to mechanical and thermal properties of ceramics as known to those familiar with the art. Densification of YAG ceramics typically requires vacuum sintering at high temperatures of about 1600° C. and higher for prolonged periods of time such as 8 hours or more to achieve a theoretical density>98%. To achieve higher densities near the theoretical value pressure assisted densification techniques such as hot isostatic pressing (HIP) are employed after vacuum sintering first to ˜98% density or uniaxial hot pressing (HP) direct from powders. Often the high temperatures and lengthy sintering durations leads to excessive grain growth, adversely affecting mechanical strength of solid yttrium aluminum oxide bodies. In order to promote densification of the YAG ceramics sintering aids such as silica (SiO₂) are often used. However, the addition of sintering aids effectively degrades the corrosion and erosion resistance of the yttrium aluminum oxide materials and increases the probability of impurity contamination at a semiconductor device level during use in chambers. Thus, a highly pure, high density body of yttrium aluminum oxide, and in particular a body having the cubic crystallographic phase (YAG, Y₃Al₅O₁₂) is desirable.

Films or coatings of yttrium aluminum oxides have been known to be deposited atop a base or substrate formed of a different material which is more readily available and possesses better mechanical and thermal properties. Such yttrium aluminum oxide films have been made through several methods. However, these methods are limited in film thicknesses that may be produced, displaying poor adhesion between film and substrate, and high levels of volumetric porosity, resulting in the shedding of particles into the process chamber.

For dense components manufactured from the YAG phase of yttrium aluminum oxide a uniform microstructure is preferable to achieve uniform corrosion properties across large areas. As such, it is desirable to obtain a high phase purity with the majority (>90% by volume) of the body consisting of YAG and minimal amounts of residual phases of alumina, yttria, YAP or YAM. However, fabrication of 100% polycrystalline YAG yttrium aluminum oxide ceramic bodies is exceedingly challenging and as such minor trace amounts, <1% by volume, of secondary oxide phases may be present. YAG according to the established yttria/alumina phase diagram only exists as a line compound in accordance with the stoichiometric composition, and thus YAG forms in a phase pure sintered body across only a very narrow compositional range. Any deviations from the nominal phase composition or an incomplete reaction between the starting phases of material can result in undesirable secondary phases in the final product.

Attempts to fabricate ceramic bodies for corrosion resistant components of large dimension made from YAG have been so far unsuccessful. Solid body, phase pure and high chemical purity components having diameters on the order of 100 mm and greater which may be handled and used as a part of a chamber without breakage or cracking are difficult to produce beyond a laboratory scale. Primarily the challenges, as previously described, can be attributed to the difficulty in sintering and the physical properties of YAG including high thermal expansion and low thermal conductivity. There are currently no economically feasible methods of making high purity, crystalline-phase pure YAG sintered bodies or components of diameter on the order of 100 mm to about 625 mm and greater for use in semiconductor etch and deposition applications.

In addition, plasma chamber components comprising a layer of YAG have been known to change color over time with UV exposure. Color changes are typically non-uniform and may result in rejection by the end user. A possible source of the coloration is the migration of metals or metal-containing compounds from substrate layers into the YAG layer during processing.

As a result, there is a need for a sintered ceramic body having uniform and high density, low porosity and high purity comprising YAG, providing enhanced plasma resistance to corrosion and erosion under plasma etch and deposition conditions, a color uniformity that does not change with UV exposure, and a commercially suitable method of production, particularly suited to fabrication of components of large dimension.

### SUMMARY

To meet these and other needs, and in view of its purposes, the disclosure provides embodiments of a multilayer sintered ceramic body and a method for preparing large, multilayer sintered ceramic bodies with improved mechanical, electrical and thermal properties and ability to be handled.

Embodiment 1. A sintered ceramic body comprising: at least one layer comprising from 90% to 99.8% by volume of polycrystalline yttrium aluminum garnet (YAG) and from 15 ppm to 500 ppm of zirconium, wherein the at least one layer comprises at least one surface, wherein the at least one surface comprises pores having a pore size not exceeding 5 μm, wherein the at least one surface exhibits an L* value of from 50 to 77, and an a* value of from 6 to 12, wherein the at least one layer has a thickness of from 500 μm to 2 cm, and wherein the values of L* and a* vary no more than 10% across the at least one surface.

Embodiment 2. The sintered ceramic body of embodiment 1 wherein the at least one layer has a b* value of from 3 to 6.

Embodiment 3. The sintered ceramic body of embodiment 2 wherein the b* value varies no more than 15% across the at least one surface.

Embodiment 4. The sintered ceramic body as in any one of the preceding embodiments wherein the at least one layer comprises from 15 to 100 ppm of zirconium.

Embodiment 5. The sintered ceramic body as in any one of the preceding embodiments wherein the thickness of the at least one layer is from 500 μm to 1 cm.

Embodiment 6. The sintered ceramic body of embodiment 4 wherein the thickness of the at least one layer is from 500 μm to 5 mm.

Embodiment 7. The sintered ceramic body as in any one of the preceding embodiments wherein the value of L* varies no more than 3% and the value of a* varies no more than 9% across the at least one surface.

Embodiment 8. The sintered ceramic body as in any one of the preceding embodiments wherein the polycrystalline yttrium aluminum garnet comprises pores having a pore size not exceeding 1.75 μm for at least 97% or more of all pores.

Embodiment 9. The sintered ceramic body as in any one of the preceding embodiments wherein the at least one polycrystalline yttrium aluminum garnet has a maximum pore size not exceeding 2 μm for at least 99% or more of all pores.

Embodiment 10. The sintered ceramic body as in any one of the preceding embodiments wherein the polycrystalline yttrium aluminum garnet has a volumetric porosity of from 0.1 to 3%.

Embodiment 11. The sintered ceramic body as in embodiment 11 wherein the volumetric porosity is from 0.1 to 2%.

Embodiment 12. The sintered ceramic body as in embodiment 11 wherein the volumetric porosity is from 0.1 to 0.5%.

Embodiment 13. The sintered ceramic body as in any one of the preceding embodiments wherein the polycrystalline yttrium aluminum garnet is present in an amount of from 93 to 99.8% by volume excluding any Al₂O₃ or zirconium present.

Embodiment 14. The sintered ceramic body as in any one of the preceding embodiments wherein the polycrystalline ceramic body has impurities of 50 ppm or less of trace metals Na, Fe, and Mg as determined by ICPMS.

Embodiment 15. The sintered ceramic body as in any one of the preceding embodiments wherein the pores occupy less than 0.2% of the surface area.

Embodiment 16. The sintered ceramic body as in any one of the preceding embodiments wherein the pores occupy less than 0.10% of the surface area.

Embodiment 17. The sintered ceramic body as in any one of the preceding embodiments and having a greatest dimension of from 100 mm to 625 mm.

Embodiment 18. The sintered ceramic body according to embodiment 17 having a greatest dimension of from 200 mm to 625 mm.

Embodiment 19. The sintered ceramic body as in embodiment 17 or 18 having a density variance of from 0.2 to less than 5% as measured across the greatest dimension.

Embodiment 20. The sintered ceramic body according to embodiment 19 having a density variance of from 0.2 to 3% as measured across the greatest dimension.

Embodiment 21. The sintered ceramic body as in any one of the preceding embodiments wherein the at least one layer comprises Al₂O₃ up to 0.5%.

Embodiment 22. A method for preparing a sintered ceramic body comprising the steps of: a) combining yttria powder, alumina powder, and a zirconium-containing powder to deliver from 15 to 500 ppm of zirconium to make a first powder mixture; b) calcining the first powder mixture by applying heat to raise the temperature of the first powder mixture to a calcination temperature and maintaining the calcination temperature to perform calcination to form a first calcined powder mixture; c) disposing the first calcined powder mixture inside a volume defined by a tool set of a sintering apparatus to form at least one layer of the first calcined powder mixture and creating vacuum conditions inside the volume; d) applying pressure to the at least one layer of the first calcined powder mixture while heating to a sintering temperature and performing sintering to form a sintered ceramic body comprising the at least one layer comprising from 90% to 99.8% by volume of polycrystalline yttrium aluminum garnet (YAG) and from 15 ppm to 500 ppm of zirconium; e) lowering the temperature of the sintered ceramic body; and f) exposing the sintered ceramic body to UV radiation for a time period of from 1 to 400 minutes, wherein the first calcined powder mixture has a total impurity content of 150 ppm or less, wherein the yttria and alumina powders in step a) each have a specific surface area of about 18 m²/g or less as measured according to ASTM C1274, wherein sintered ceramic layer comprises at least one layer comprising from 90% to 99.8% by volume of polycrystalline yttrium aluminum garnet (YAG) and from 15 ppm to 500 ppm of zirconium, wherein the at least one layer comprises at least one surface, wherein the at least one surface comprises pores having a pore size not exceeding 5 μm and having a maximum pore size of 1.5 μm for at least 95% of the pores, wherein the at least one surface exhibits an L* value of from 50 to 77, and an a* value of from 6 to 12, wherein the at least one layer has a thickness of from 500 μm to 2 cm, and wherein the values of L* and a* vary no more than 10% across the at least one surface.

Embodiment 23. The method of embodiment 22 further comprising the following steps: g) annealing the sintered ceramic body by applying heat to raise the temperature of the sintered ceramic body to reach an annealing temperature and performing annealing; h) lowering the temperature of the annealed multilayer sintered ceramic body; and i) optionally machining the sintered ceramic body or the annealed sintered ceramic body to create a sintered ceramic component in the shape of a dielectric window, an RF window, a focus ring, a process ring, a deposition ring, a nozzle or a gas injector, a shower head, a gas distribution plate, an etch chamber liner, a plasma source adapter, a gas inlet adapter, a diffuser, an electrostatic wafer chuck (ESC), a chuck, a puck, an ion suppressor element, a faceplate, an isolator, a spacer, and/or a protective ring in plasma processing chambers.

Embodiment 24. The method of embodiment 22 or 23 wherein the tool set comprises a graphite die having a volume, an inner wall, a first and second openings, and first and second punches operatively coupled with the die, wherein each of the first and second punches have an outer wall defining a diameter that is less than a diameter of the inner wall of the die thereby creating a gap between each of the first and second punches and the inner wall of the die when at least one of the first and second punches moves within the volume of the die.

Embodiment 25. The method of embodiment 24 wherein the gap is a distance of from 10 to 100 μm between the inner wall of the die and the outer wall of each of the first and second punches.

Embodiment 26. The method according to one of embodiments 22 to 25 wherein the sintering temperature is from 1000 to 1500° C.

Embodiment 27. The method as in any one of embodiments 22 to 26 wherein the sintering temperature is from 1000 to 1300° C.

Embodiment 28. The method as in any one of embodiments 22 to 27 wherein from 5 to 59 MPa of pressure is applied to the calcined powder mixture while heating to the sintering temperature.

Embodiment 29. The method according to embodiment 28 wherein the pressure is from 5 to 40 MPa.

Embodiment 30. The method according to embodiment 29 wherein the pressure is from 5 to 20 MPa.

Embodiment 31. The method as in any one of embodiments 22 to 30 wherein less than 50 MPa of pressure is applied to the calcined powder mixture while heating to the sintering temperature.

Embodiment 32. The method as in any one of embodiments 22 to 31 wherein the sintered ceramic body has a greatest dimension of from 100 mm to 625 mm.

Embodiment 33. The method according to embodiment 32 wherein the sintered ceramic body has a greatest dimension of from 200 mm to 625 mm.

Embodiment 34. The method as in any one of embodiments 22 to 33 wherein the sintered ceramic body has a density variance of from 0.2 to less than 5% as measured across the greatest dimension.

Embodiment 35. The method according to embodiment 34 wherein the sintered ceramic body has a density variance of from 0.2 to 3% as measured across the greatest dimension.

Embodiment 36. The method as in any one of embodiments 22 to 35 wherein the at least one surface exhibits a b* value of from 3 to 6.

Embodiment 37. The method according to embodiment 36 wherein the b* value varies no more than 15% across the at least one surface.

Embodiment 38. The sintered ceramic body according to embodiment 14 wherein the polycrystalline ceramic body has impurities of 5 ppm or less of trace metals Na, Fe, and Mg as determined by ICPMS.

The embodiments of the invention can be used alone or in combinations with each other.

### BRIEF DESCRIPTION OF THE DRAWINGS

FIG. 1 depicts the phase diagram of the two-component yttrium oxide/aluminum oxide phase diagram, illustrating the yttrium aluminum oxide phases of YAG (Y₃Al₅O₁₂), YAP (YAlO₃) and YAM (Y₄Al₂O₉) and the molar proportions and temperatures necessary to form them;

FIG. 2A is an SEM micrograph at 10,000× of a polished surface of a sintered ceramic body made according to Example 2; and

FIG. 2B is an SEM micrograph at 10,000× of a polished surface of a sintered ceramic body made according to Example 2.

### DETAILED DESCRIPTION

Reference will now be made in detail to specific embodiments. While the disclosure will be described in conjunction with these specific implementations, it will be understood that it is not intended to limit the disclosure to such specific embodiments. On the contrary, it is intended to cover alternatives, modifications, and equivalents as may be included within the spirit and scope as defined by the appended claims. In the following description, numerous specific details are set forth to provide a thorough understanding of the disclosed embodiments. The present disclosure may be practiced without some of, or all of, these specific details.

Semiconductor etch and deposition reactors require reactor components having surfaces which have high resistance to corrosion and erosion by halogen containing plasmas necessary for processing. The surfaces preferably minimize release of particles from the component surface into the chamber. Additionally, chamber components must possess enough mechanical strength for handleability and use, in particular at large (>100 mm in diameter, e.g., from 100 to 625 mm) component dimensions. The sintered ceramic bodies may be machined into sintered components and as such, must be able to be handled and machined at large dimension while providing corrosion resistance, low particle generation and high mechanical strength. The sintered ceramic bodies as disclosed herein comprise at least one layer comprising from 90% to 99.8% by volume of polycrystalline yttrium aluminum garnet (YAG) and from 15 ppm to 500 ppm of zirconium, wherein the at least one layer comprises at least one surface, wherein the at least one surface comprises pores having a pore size not exceeding 5 μm and having a maximum pore size of 1.5 μm for at least 95% of the pores, wherein the at least one surface exhibits an L* value of from 50 to 77, and an a* value of from 6 to 12, wherein the at least one layer has a thickness of from 500 μm to 2 cm, and wherein the values of L* and a* vary no more than 10% across the at least one surface. These materials have excellent corrosion and erosion resistance. The use of these materials results in a semiconductor plasma processing chamber component having a surface which provides improved plasma resistance over other materials when subjected to halogen-based plasma etch and deposition conditions.

### Definitions

As used herein, the term “yttrium aluminum oxide” is understood to mean at least one of the forms of crystalline phases of yttrium aluminum oxides, including Y₃Al₅O₁₂ (YAG; yttrium aluminum garnet/cubic phase), YAlO₃ (YAP; yttrium aluminum perovskite phase), and Y₄Al₂O₉(YAM; yttrium aluminum monoclinic phase) and combinations of these. The terms “YAG” and “YAG phase” are used interchangeably herein.

As used herein, the term “sintered ceramic body” is refers to a single or multilayer body. If a multilayered body, the term refers to a unitary, integral sintered ceramic article formed from co-compacting one or more than one powder mixtures by application of pressure and heat which creates a unitary, dense, multilayer sintered ceramic body. The unitary, multilayer sintered ceramic body may be machined into a unitary, multilayer sintered ceramic component useful as a chamber component in plasma processing applications. As used herein, the term “co-compacting” or “co-compaction” refers to the process by which at least two loose powder materials are disposed within a die and subjected to pressure to form a powder compact. The powder compact is free of binders, dispersants, and other similar organic matter as is required for the formation of green or shaped bodies, or tapes as is common in the art.

By “unitary” or “integral” is meant a single piece or a single unitary part that is complete by itself without additional pieces, i.e., the part is of one monolithic piece formed as a unit with another part.

The term “substantially,” as used in this document, is a descriptive term that denotes approximation and means “considerable in extent” or “largely but not wholly that which is specified” and is intended to avoid a strict numerical boundary to the specified parameter.

As used herein, the term “sintered ceramic component” or “multilayer sintered ceramic component” refers to a single layer sintered ceramic body, multilayer sintered ceramic body or corrosion resistant ceramic after a machining step forming the ceramic into a specific shape of a desired component for use in a semiconductor processing chamber as disclosed herein.

As used herein, the term “powder mixture” means more than one starting powder mixed together prior to a sintering process which after a sintering step are thereby formed into at least one layer of the multilayer sintered ceramic body.

The term “annealing” when applied to heat treatment of ceramics is understood herein to mean a heat treatment conducted on the disclosed multilayer sintered ceramic bodies in air to relieve stress and/or normalize stoichiometry.

As used herein, the term “tool set” is one that may comprise at least a die and at least two punches. When fully assembled, the tool set defines a volume for disposition of the powder mixtures as disclosed.

The term “phase” as used herein is understood to mean a distinct, crystalline region, portion or layer of a sintered ceramic body having a specific crystallographic structure.

A “solid solution” as used herein is defined as a mixture of different elements that share the same crystal lattice structure. The mixture within the lattice may be substitutional, in which the atoms of one starting crystal replace those of the other, or interstitial, in which the atoms occupy positions normally vacant in the lattice.

As used herein, the term “nanopowder” is intended to encompass those powders having a specific surface area of greater than 20 m²/g.

The term “phase” as used herein is understood to mean a distinct, crystalline region, portion or layer of a sintered ceramic body having a specific crystallographic structure.

As used herein, the term “layer” is understood to mean a thickness of material, typically one of several. The material can be, for example, a ceramic powder, a powder mixture, a calcined powder mixture, or a sintered region or sintered portion.

As used herein, “ambient temperature” refers to a temperature range of from about 22° C. to 25° C.

As used herein, the term “purity” refers to the absence of various contaminants in a) a starting material from which a powder mixture may be formed, b) a powder mixture (or calcined powder mixture) after processing, and c) a multilayer sintered ceramic body or component as disclosed herein. Higher purity, closer to 100%, represents a material having essentially no, or very low amounts of, contaminants or impurities, comprising substantially the material compositions present in the starting powders as disclosed.

As used herein, the term “impurity” refers to those compounds/contaminants present in the powders or sintered ceramics other than the intended compounds themselves. Impurities may be present in the starting powders, a powder mixture, the powder mixture after processing, and a sintered ceramic body. ICPMS methods were used to determine the impurity content of the powders, powder mixtures and first and second layers of the sintered body as disclosed herein.

The term “dopant” as used herein is a substance added to a bulk material to produce a desired characteristic in a ceramic material (e.g., to alter electrical properties). Typically, dopants if used are present at low concentrations, i.e., >0.002 wt. % to <0.05 wt.

Impurities differ from dopants in that dopants as defined herein are those compounds intentionally added to the starting powders or to the powder mixture to achieve certain electrical, mechanical, optical or other properties such as grain size modification for example, in the multilayer sintered ceramic body.

The term “sintering aid” as used herein refers to compounds, such as silica (SiO₂), lithia (Li₂O), lithium fluoride (LiF), magnesia (MgO), and/or calcia (CaO), that enhance densification, and thereby reduce porosity, during the sintering process. Hf and Y present in the starting powders and to the extent they remain in the sintered ceramic do not comprise sintering aids, impurities or dopants as defined herein.

As used herein, the terms “approximately,” and “about” as they are used in connection with numbers or features as disclosed herein allow for a variance of plus or minus 10%.

The following detailed description assumes the disclosure is implemented within equipment such as etch or deposition chambers necessary as part of the making of devices upon a semiconductor wafer substrate. However, the invention is not so limited. The work piece may be of various shapes, sizes, and materials. In addition to semiconductor wafer processing, other work pieces that may take advantage of this invention include various articles such as fine feature size inorganic circuit boards, magnetic recording media, magnetic recording sensors, mirrors, optical elements, micro-mechanical devices and the like.

During processing of semiconductor devices, corrosion resistant parts or chamber components are used within etch chambers and exposed to harsh corrosive environments which cause the release of particles into the etch chamber, resulting in yield loss due to wafer-level contamination. The sintered ceramic body and related components as disclosed herein provide improved plasma etch resistance and enhanced ability to be cleaned within semiconductor processing chambers by way of specific material properties and features to be described following.

### YAG

In an embodiment, disclosed herein is a sintered ceramic body comprising at least one layer comprising from 90% to 99.8% by volume of polycrystalline yttrium aluminum garnet (YAG) and from 15 ppm to 500 ppm of zirconium, wherein the at least one layer comprises at least one surface, wherein the at least one surface comprises pores having a pore size not exceeding 5 μm and having a maximum pore size of 1.5 μm for at least 95% of the pores, wherein the at least one surface exhibits an L* value of from 50 to 77, and an a* value of from 6 to 12, wherein the at least one layer has a thickness of from 500 μm to 2 cm, and wherein the values of L* and a* vary no more than 10% across the at least one surface. In embodiments, the sintered ceramic body has a volumetric porosity of from 0.1 to 4% as calculated from density measurements performed in accordance with ASTM B962-17.

The sintered ceramic body comprises at least one layer and, thus, in some embodiments is a single layer sintered ceramic body comprising from 90% to 99.8% by volume of polycrystalline yttrium aluminum garnet (YAG) and from 15 ppm to 500 ppm of zirconium and having the characteristics disclosed herein. In other embodiments, the sintered ceramic body is a multilayer sintered ceramic body comprising at least one layer comprising from 90% to 99.8% by volume of polycrystalline yttrium aluminum garnet (YAG) and from 15 ppm to 500 ppm of zirconium and having the characteristics disclosed herein. In multilayer embodiments, the at least one layer comprising from 90% to 99.8% by volume of polycrystalline yttrium aluminum garnet (YAG) and from 15 ppm to 500 ppm of zirconium and having the characteristics disclosed herein is preferably an outer layer so it can, ultimately in use, be a surface exposed to plasma in a plasma processing chamber. A second layer may be any suitable material such as, for example, zirconia toughened alumina or yttrium oxide.

In embodiments, the sintered ceramic body comprises at least one layer comprising polycrystalline YAG in an amount of from 90 to 99.6% by volume, preferably from 90 to 99.4% by volume, preferably from 95 to 99.6% by volume, preferably from 95 to 99.4% by volume of a cubic crystallographic structure through use of the materials and methods as disclosed herein. In certain embodiments, the sintered ceramic body as disclosed herein may comprise from 95 and 99.6% by volume of the cubic crystalline phase of YAG and from 0.01 to 5% of an aluminum oxide phase. The volumetric values of the cubic crystalline phase of YAG as disclosed herein exclude any Al₂O₃ and zirconium containing compounds. Embodiments of the sintered ceramic body as disclosed herein are polycrystalline and as such the sintered ceramic body may comprise two or more crystals, without limitation. The sintered ceramic body may comprise volumetric porosity in amounts of from 0.1 to 4%, preferably from 0.1 to 3%, preferably from 0.1 to 2%, preferably from 0.1 to 1%, and preferably from 0.1 to 0.5%, wherein the volumetric porosity is calculated from density measurements performed in accordance with ASTM B962-17 or ASTM B311-17 if porosity is less than 2%.

In another embodiment, disclosed herein is a sintered ceramic body comprising at least one layer comprising yttrium aluminum garnet (YAG) of composition Y₃Al₅O₁₂ comprises from 90 to 99.8% by volume of a cubic crystallographic structure and aluminum oxide in an amount from 0.2 to 10% by volume, preferably from 0.2 to 8% by volume, preferably from 0.2 to 5% by volume, preferably from 0.2 to 3% by volume, preferably from 0.2 to 2% by volume, and preferably from 0.2 to 1% by volume of aluminum oxide.

In embodiments, the at least one layer of the sintered ceramic body comprises at least one form of polycrystalline yttrium aluminum oxide in an amount by volume of from 70 to 100% as determined by x ray diffraction, a volumetric porosity of from 0.1 to less than 5% as calculated from density measurements performed in accordance with ASTM B962-17, a purity of greater than 99.99% as measured by ICPMS method, and a hardness of at least 1200 HV as measured in accordance with ASTM Standard C1327. In embodiments, the at least one layer of the sintered ceramic body comprises at least one polycrystalline yttrium aluminum oxide phase or a combination of the phases of yttrium aluminum oxides, to include in specific embodiments yttrium aluminum garnet the Y₃Al₅O₁₂ (YAG) phase, yttrium aluminum perovskite YAlO₃ (YAP), and yttrium aluminum monoclinic Y₄Al₂O₉(YAM) and combinations thereof. In preferred embodiments, the sintered ceramic body comprises from 90% to 99.8% by volume of polycrystalline yttrium aluminum garnet (YAG).

In an embodiment, the at least one layer of the sintered ceramic body as disclosed herein may comprise about 100% of a single crystalline phase of any one of the yttrium aluminum oxides of YAG, YAP or YAM. In other embodiments, the sintered ceramic body may comprise a matrix or composite structure of two or more discrete or continuous phases of the yttrium aluminum oxides as disclosed herein. In further embodiments, the sintered ceramic body may comprise minority phases of aluminum oxide and/or yttrium oxide with a majority of any one or combination of the yttrium aluminum oxides YAG, YAP and YAM.

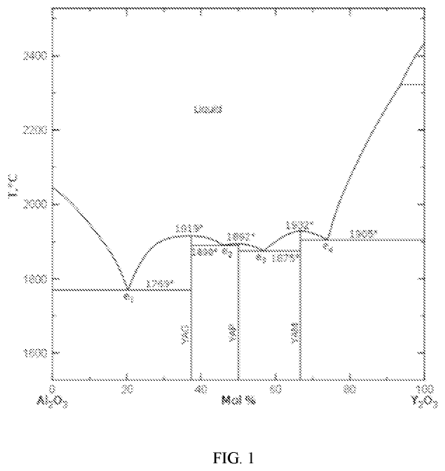

As a guide, FIG. 1 depicts the yttrium oxide/aluminum oxide two-component phase diagram. The horizontal axis corresponds to mixture proportions in mole percent of yttria and alumina, while the vertical axis is temperature in Celsius. The left of the horizontal axis corresponds to 100% alumina while the right corresponds to 100% yttria. The phase diagram of FIG. 1 illustrates regions where the yttrium aluminum oxide phases of YAG, YAP, and YAM are formed and the conditions of molar composition and temperature necessary to produce the forms. The formation of YAG may require precise batching of powders and careful processing in order to maintain stoichiometry and thus form a sintered ceramic body comprising phase pure YAG of 37.5 mol % yttrium oxide and 62.5 mol % aluminum oxide.

### Color

The at least one layer of the sintered ceramic body disclosed herein comprises from 15 ppm to 500 ppm of zirconium as a dopant and has at least one surface that exhibits an L* value of from 50 to 77, an a* value of from 6 to 12, and a b* value of from 3 to 6 upon exposure to UV radiation. Without intending to be bound by a particular theory, it is believed that the YAG phase provides a host matrix into which zirconium atoms penetrate as a solid solution. Thus, the upper limit of the zirconium is the amount up to which the zirconium is no longer in solid solution and forms a separate phase. Zirconium at the lower end of the range is preferably enough to impart a uniform red color to the YAG matrix when the at least one surface is exposed to UV radiation. The purpose of the added (i.e., doped) zirconium is to affect a uniform color change to red once the sintered ceramic body is exposed to UV radiation as detailed below. In embodiments, the zirconium may be present in an amount of from 15 ppm to 500 ppm, from 15 ppm to 100 ppm, from 15 ppm to 250 ppm, from 50 ppm to 250 ppm, from 50 ppm to 225 ppm, from 50 ppm to 200 ppm, from 50 ppm to 175 ppm, from 50 ppm to 150 ppm, from 50 ppm to 150 ppm, from 50 ppm to 125 ppm, from 50 ppm to 100 ppm, and from 50 ppm to 75 ppm.

The above-mentioned quantities of zirconium can be added as an oxide, chloride, nitrate, or any other counter ion. Preferably, the zirconium is added as an oxide.

“Color” is described using the 1976 CIELAB color space (standard ISO 11664-4 defined by the International Commission on Illumination): this reduces color to a lightness/darkness variable L*, for which absolute black is 0 and complete white is 100, and other parameters a* and b* which describe the hue of the object. Typically, an object having L* greater than 65 and less than 82, and absolute values of a* and b* of less than 5 are considered white. Uniformity and lightness may be assessed visually by eye or, preferably, measured using commercially available instrumentation such as a FRU WR-18 colorimeter, as one non-limiting example, using the CIELAB L*a*b* scale. CIELAB L*a*b* values are also referred to as CIE Lab values or L*, a*, b* values interchangeably herein. Values for “a*” refer to the redness-greenness coordinate in certain transformed color spaces, generally used as the difference in “a*” between a specimen and a standard reference color. If “a*” is positive, there is more redness than greenness; if “a*” is negative, there is more greenness than redness. The value for a*is normally used with b*as part of the chromaticity or chromaticity color difference. Values for “b*” refer to the yellowness-blueness coordinate in certain color spaces, generally used as the difference in “b*” between a specimen and a standard reference color, normally used with “a*” or a as part of the chromaticity difference. Generally, if “b*” is positive, there is more yellowness than blueness; if “b*” is negative, there is more blueness than yellowness.

The at least one layer of the sintered ceramic body disclosed herein has at least one surface that exhibits an L* value of from 50 to 77 and, in some embodiments, from 50 to 60, an a* value of from 6 to 12, and a b* value of from 3 to 6 upon exposure to UV radiation. The “color” produced upon exposure to UV radiation is uniform in that the L* and a* values do not vary more than 10% and, in some embodiments, no more than 3.0%, and in other embodiments not more than 1.5%; and the b* value varies by no more than 15% and, in some embodiment, by no more than 7% and preferably by no more than 3% across the at least one surface. In one embodiment, the value of L* varies no more than 3% and the value of a* varies no more than 9% across the at least one surface. Tables 1 and 2 show the differences in color uniformity of a colored 22 inch (558.8 mm) (2,452 cm²) YAG piece having 50 ppm of doped zirconium made according to the process disclosed herein (Table 1) versus a 22 inch YAG piece having a non-uniform distribution of ppm of zirconium as a result of migration of zirconium from an underlying layer of zirconia-toughened aluminum made according to the process disclosed herein. In other words, both samples of Tables 1 and 2 were two-layer sintered ceramic bodies each having a substrate layer of zirconia-toughened aluminum and a top layer comprising YAG, however, the sample of Table 1 comprised a YAG layer that was intentionally doped with 50 ppm of zirconium and the YAG layer of sample of Table 2 was not but did have some zirconium by way of migration during the manufacturing process. Color uniformity is important not only for the perception of chemical and physical uniformity but for uniformity of emissivity because darker areas will absorb heat more than lighter areas causing hot spots that may cause cracks to form during use.

TABLE 1
Uniform Color Example

| | L* | a* | b* |
|---|---|---|---|
| | 55.68 | 8.5 | 4.3 |
| | 54.64 | 8.93 | 4.38 |
| | 56.14 | 8.01 | 3.96 |
| | 59.61 | 7.19 | 3.18 |
| | 58.55 | 7.79 | 3.89 |
| | 58.4 | 7.27 | 3.56 |
| | 57.32 | 7.13 | 3.13 |
| | 56.08 | 7.58 | 3.61 |
| | 55.56 | 8.92 | 4.72 |
| | 56.74 | 8.89 | 4.65 |
| Average | 56.87 | 8.02 | 3.94 |
| St. Dev | 1.49 | 0.70 | 0.54 |
| % Deviation | 2.6 | 8.7 | 13.7 |

TABLE 2
Non-Uniform Color Example

| | L* | a* | b* |
|---|---|---|---|
| | 37.23 | 6.16 | 1.83 |
| | 35.91 | 6.26 | 2.29 |
| | 77.42 | 6.57 | 4.73 |
| | 59.21 | 7.65 | 4.06 |
| | 40.75 | 7 | 2.67 |
| | 39.85 | 7.06 | 2.94 |
| | 37.18 | 1.71 | −1.63 |
| | 36.76 | 5.54 | 0.12 |
| | 55.32 | 8.08 | 4.54 |
| Average | 46.63 | 6.23 | 2.39 |
| St. Dev | 13.55 | 1.76 | 1.97 |
| % Deviation | 29.1 | 28.2 | 82.2 |

The YAG layer of the sample of Table 1 had a relative density of 99.9% and the YAG layer of the sample of Table 2 had a relative density of 99.8%, thus, the YAG layer of the sample of Table 2 was more porous than the YAG layer of the sample of Table 1.

### Porosity and Density

The at least one layer of the sintered ceramic body disclosed herein is very dense and, correspondingly, has a very small pore profile such that the at least one surface comprises pores having a pore size not exceeding 5 μm. In embodiments, the pores have a maximum pore size of 1.5 μm for at least 95% of the pores.

In order to assess grain size of the at least one first layer comprising polycrystalline YAG, linear intercept grain size measurements were performed in accordance with the Heyn Linear Intercept Procedure described in ASTM standard E112-2010 “Standard Test Method for Determining Average Grain Size.” Grain size measurements were performed (as listed in Table 3) and an average grain size of from 1.1 to 6.3 um was measured across 25 repetitions. A maximum and minimum grain size of from 2 to 7.7 um were also measured on a surface of the at least one first layer comprising YAG. The unitary, multilayer sintered ceramic body may have a surface having a grain size of, for example, a maximum grain size of about 8 um and less, preferably a maximum grain size of 6 um and less. In embodiments, the unitary, multilayer sintered ceramic body may have a surface having an average grain size of from 0.4 to 6.5 um, preferably from 0.4 to 5 um, preferably from 0.4 to 3 um, preferably from 0.8 to 6.5 um, preferably from 0.8 to 5 um, preferably from 0.8 to 3 um, preferably from 1 to 7 um, preferably from 1 to 6.5 um.

TABLE 3

| | Average | Median | | | | |
|---|---|---|---|---|---|---|
| Sample_{—} | Grain Size | (d50) | d90 | Min | Max | |
| (μm) | (μm) | (μm) | (μm) | (um) | (um) | |
| 519 | 1.1 | 2.1 | 1.8 | 3.1 | 0.5 | 7 |
| 531 | 0.6 | 1.1 | 1.0 | 1.5 | 0.4 | 2 |
| 506 | n/a | 6.3 | n/a | n/a | 5 | 7.7 |

Density measurements were performed using the Archimedes buoyancy method according to ASTM B962-17 and ASTM B311-17 (when porosity levels are 2% and less). Density values and standard deviations reported are for an average across 5 or more measurements. A commercially available, single crystal sample of YAG was measured for density using the methods as disclosed herein. A commercially available, single crystal sample of bulk YAG was measured for density using the methods as disclosed herein. An Archimedes density of 4.56 g/cc across 5 measurements was obtained and this value is taken as the theoretical density of YAG as used herein. The sintered ceramic bodies comprising at least one layer of phase pure YAG and further phase pure YAG including up to 1% by weight excess alumina as disclosed in embodiments herein may have density of for example from 4.374 to 4.556 g/cc, from 4.419 to 4.556 g/cc, from 4.465 to 4.556 g/cc, from 4.510 to 4.556 g/cc, and from 4.533 to 4.556 g/cc, or by percentage of from 96 to 99.999%, from 97 to 99.999%, 98 to 99.999%, from 99 to 99.999%, and from 99.5 to 99.999% of theoretical density of YAG. Corresponding volumetric porosities (Vp) may be from 0.010 to less than 5%, from 0.010 to 4%, from 0.010 to 3%, from 0.010 to 3%, from 0.010 to 2%, from 0.010 to 1%, preferably less than 1%, preferably less than 0.5% as calculated from the density measurements performed as disclosed herein. In embodiments where the ceramic sintered body comprises at least one second layer comprising about 16% by volume of at least one of stabilized and partially stabilized zirconia (and the balance alumina), density was measured under similar conditions and a density of about 4.32 g/cc was calculated. The volumetric mixing rule was used to calculate a theoretical density of ZTA comprising about 16% by volume of zirconia, and a density of 4.32 was measured and taken as the theoretical density of the at least one second layer comprising about 16 volume % zirconia. As such, the at least one second layer of the multilayer sintered ceramic body comprising about 16% by volume of zirconia has a percent of theoretical density of from 99 to 100%, preferably from 99.5 to 100%, preferably about 100% of that of the theoretical density. The multilayer sintered ceramic body as disclosed in accordance with this embodiment has a % of theoretical density (also expressed as relative density, RD) which is greater than 99%, preferably from 99 to 100%, preferably from 99.5 to 100%, preferably about 100% of the theoretical density of the unitary, multilayer sintered ceramic body comprising at least one first and second layers.

The relative density (RD) for a given material is defined as the ratio of the measured density of the sample to the reported theoretical density for the same material, as shown in the following equation. Volumetric porosity (Vp) is calculated from density measurements as follows:

$$R D = \frac{ρ sample}{ρ theoretical} = 1 - V p$$

where ρ sample is the measured (Archimedes) density according to ASTM B962-17, ρ theoretical is the reported theoretical density, and RD is the relative fractional density. Using this calculation, porosity levels by percent of from 0.1 and 5% and less were calculated from measured density values for the sintered ceramic bodies as disclosed herein. Thus, in embodiments, the sintered ceramic body comprising at least one yttrium aluminum oxide garnet phase as disclosed herein comprises volumetric porosity in amounts of from 0.1 to 5%, preferably from 0.1 to 4%, preferably from 0.1 to 3%, preferably from 0.1 to 2%, preferably from 0.1 to 1% in the sintered ceramic body as calculated from the corresponding density.

These density, purity and porosity levels may provide enhanced resistance to the effects of erosion and corrosion resulting from plasma etch and deposition processing. The method and materials as disclosed are particularly useful in the preparation of ceramic sintered bodies of large dimension, for example from a greatest dimension of from 200 to about 625 mm. The high densities, and thereby high mechanical strength, of the ceramic sintered body also provide increased handleability, in particular at large dimensions. Successful fabrication of sintered yttrium aluminum oxide bodies, and in particular bodies formed of phase pure YAG in ranges as disclosed herein, across a longest (from about 200 to about 625 mm) dimension may be enabled by controlling variation in density across at least one, longest dimension. An average density of 96% and greater is desirable, with a variation in density of from 0.2 to less than 5% and less, preferably 4% and less, preferably 3% and less, preferably 2% and less, and preferably 1% and less as measured across the greatest dimension, whereby the greatest dimension may be for example from 100 to 625 mm, preferably from 100 to 622 mm, preferably from 100 to 575 mm, preferably from 200 to 625 mm, preferably from 200 to 510 mm, preferably from 400 to 625 mm, and preferably from 500 to 625 mm. Low densities of less than 95% of theoretical density for YAG may have lower strengths and thereby higher porosities, in excess of 5%, which results in breakage and inferior handleability.

Along with high density, the variation in density across a greatest dimension of the ceramic sintered body as disclosed may impact the ability to be handled in particular at large (>100 mm) dimension, machined and use as a ceramic sintered component. The density was measured across a greatest dimension of several examples of ceramic sintered bodies as disclosed herein.

In addition to high density, high hardness values may further provide enhanced resistance to erosion during use as a plasma chamber component. As such, Vickers hardness measurements were performed in accordance with ASTM Standard C1327 “Standard Test Method for Vickers Indentation Hardness of Advanced Ceramics.” The test equipment used for all hardness measurements was a Wilson Micro Hardness Tester Model VH1202. Hardness values of at least 1200 HV, preferably at least 1400 HV, preferably at least 1800 HV, preferably at least 2000 HV, from 1300 to 1600 HV, from 1300 to 1500 HV, from 1300 to 1450 HV, from 1300 to 1400 HV, from 1400 to 1600 HV, from 1450 and 1600 HV, from 1450 and 1550 HV may be obtained for the ceramic sintered body as disclosed herein. Measurements may be obtained using Vickers hardness methods as known in the art were converted to SI units of GPa. Hardness values of from 12.75 to 15.69 GPa, from 12.75 to 14.71 GPa, from 12.75 to 14.22 GPa, from 12.75 to 13.73 GPa, from 13.73 and 15.69 GPa, from 14.22 and 15.69 GPa, preferably from 14.22 and 15.20 GPa may be obtained for the ceramic sintered body as disclosed herein. These high hardness values may contribute to enhanced resistance to ion bombardment during semiconductor etch processes and reduced erosion during use, providing extended lifetimes when the ceramic sintered body is machined into ceramic sintered components having fine scale features.

In one embodiment, the sintered ceramic body disclosed herein has an average hardness of from 13.0 to 15.0 GPa for eight samples using an applied load of 0.2 kgf as measured in accordance with ASTM Standard C1327. In another embodiment, the ceramic sintered body disclosed herein has an average hardness of about 13.5 to 14.5 GPa for eight samples using an applied load of 0.2 kgf as measured in accordance with ASTM Standard C1327.

Mechanical strength properties are known to improve with decreasing grain size. In order to assess grain size, linear intercept grain size measurements were performed in accordance with the Heyn Linear Intercept Procedure described in ASTM standard E112-2010 “Standard Test Method for Determining Average Grain Size.” Grain size may also be measured by SEM. To meet the requirements of high flexural strength and rigidity for use in reactor chambers as large components of from 200 to 625 mm, the ceramic sintered body may have a fine grain size of, for example, a maximum grain size of about 10 um and less, preferably a maximum grain size of 8 um and less, preferably an average grain size of 5 um and less, preferably an average grain size of 3 um and less, preferably 2 um and less, preferably 1.5 um and less, preferably 1.0 um and less, preferably from 0.5 and 8 um, preferably a grain size of from 1 to 5 um.

The at least one layer comprising from 90% to 99.8% by volume of polycrystalline yttrium aluminum garnet (YAG) and from 15 ppm to 500 ppm of zirconium may have a total impurity content of less than 100 ppm, preferably less than 75 ppm, less than 50 ppm, preferably less than 25 ppm, preferably less than 15 ppm, preferably less than 10 ppm, preferably less than 8 ppm, preferably less than 5 ppm, preferably from 5 to 30 ppm, and preferably from 5 to 20 ppm relative to a total mass of the at least one first layer comprising polycrystalline YAG and from 15 ppm to 500 ppm of zirconium as measured using ICPMS methods. The total impurity contents as disclosed herein do not include Si in the form of silica.

Detection limits using the ICP-MS methods as disclosed herein to identify presence of lighter elements are higher than reporting limits of heavier elements. In other words, heavier elements, such as from Sc and higher, are detected with greater accuracy, for example to as low as 0.06 ppm, than those lighter elements, from for example Li to Al (detected at for example accuracy of as low as 0.7 ppm). Thus, impurity contents for those powders comprising lighter elements, such as from Li to Al, may be determined to about 0.7 ppm and greater, and impurity contents of heavier elements, from Sc (scandium) to U (uranium) may be determined to about 0.06 ppm and greater. Using the ICPMS methods as disclosed herein, silica may be detected in amounts as low as about 14 ppm, while K (potassium) and Ca (calcium) may be identified in amounts of 1.4 ppm and greater. Iron may be detected with accuracy in amounts of as low as 0.14 ppm.

The sintered ceramic body comprising at least one layer comprising from 90% to 99.8% by volume of polycrystalline yttrium aluminum garnet (YAG) and from 15 ppm to 500 ppm of zirconium, wherein the at least one layer comprises at least one surface, wherein the at least one surface comprises pores having a pore size not exceeding 5 μm and having a maximum pore size of 1.5 μm for at least 95% of the pores, wherein the at least one surface exhibits an L* value of from 50 to 77, and an a* value of from 6 to 12, wherein the at least one layer has a thickness of from 500 μm to 2 cm, and wherein the values of L* and a* vary no more than 10% across the at least one surface as disclosed herein can be a single layer sintered ceramic body or it could be a layer of a multilayer sintered ceramic body.

If a multilayer sintered ceramic body comprising one or more additional layers, the one or more additional layers may be, for example, one or more of (i) alumina wherein the alumina comprises at least one of stabilized zirconia and partially stabilized zirconia; (ii) an additional YAG layer; (iii) yttria; and (iv) alumina.

In some embodiments, the at least one first layer comprising YAG may have a purity of 99.99% and greater, preferably 99.995% and greater (excluding Al₂O₃ and zirconium-containing compounds), each relative to a material having 100% purity as measured using the ICPMS methods as disclosed herein.

The above-mentioned characteristics of the corrosion resistant component formed from the ceramic sintered body are achieved by adapting the purity of the powders of yttrium oxide and aluminum oxide, the combining of the powders, the calcination of the powders, the pressure to the powders of yttrium oxide and aluminium oxide, the temperature of the powders of yttrium oxide and aluminium oxide, the duration of sintering the powders, the temperature of the ceramic sintered body/ceramic sintered component during the optional annealing step, and the duration of the optional annealing step. The method as disclosed herein is suitable for the production of ceramic sintered bodies, in particular those of large dimension, using a scalable manufacturing process.

### Method of Preparation

Preparation of the sintered ceramic bodies disclosed herein may be achieved by use of pressure assisted sintering, such as for example Spark Plasma Sintering (SPS), also known as Field Assisted Sintering Technology (FAST), or Direct Current Sintering (DCS). These direct current sintering and related techniques employ a direct current to heat up an electrically conductive die configuration or tool set, and thereby a material to be sintered. This manner of heating allows the application of very high heating and cooling rates, enhancing densification mechanisms over grain growth promoting diffusion mechanisms, which may facilitate preparation of sintered ceramic bodies of very fine grain size, and transferring the intrinsic properties of the original powders into their near or fully dense products. The direct current, pressure assisted methods as disclosed herein utilize a preferably unpulsed, continuous direct current to heat the tool set as disclosed.

Disclose herein is a method for preparing a sintered ceramic body as disclosed above comprising at least one layer comprising from 90% to 99.8% by volume of polycrystalline yttrium aluminum garnet (YAG) and from 15 ppm to 500 ppm of zirconium, wherein the at least one layer comprises at least one surface, wherein the at least one surface comprises pores having a pore size not exceeding 5 μm and having a maximum pore size of 1.5 μm for at least 95% of the pores, wherein the at least one surface exhibits an L* value of from 50 to 77, and an a* value of from 6 to 12, wherein the at least one layer has a thickness of from 500 μm to 2 cm, and wherein the values of L* and a* vary no more than 10% across the at least one surface. The method comprises the steps of: a) combining yttria powder, alumina powder, and a zirconium-containing powder to deliver from 15 to 500 ppm of zirconium to make a first powder mixture; b) calcining the first powder mixture by applying heat to raise the temperature of the first powder mixture to a calcination temperature and maintaining the calcination temperature to perform calcination to form a first calcined powder mixture; c) disposing the first calcined powder mixture inside a volume defined by a tool set of a sintering apparatus to form at least one layer of the first calcined powder mixture and creating vacuum conditions inside the volume; d) applying pressure to the at least one layer of the first calcined powder mixture while heating to a sintering temperature and performing sintering to form a sintered ceramic body comprising the at least one layer comprising from 90% to 99.8% by volume of polycrystalline yttrium aluminum garnet (YAG) and from 15 ppm to 500 ppm of zirconium; e) lowering the temperature of the sintered ceramic body; and f) exposing the sintered ceramic body to UV radiation for a time period of from 1 to 200 minutes, wherein the first calcined powder mixture has a total impurity content of 150 ppm or less, wherein the yttria and alumina powders in step a) each have a specific surface area of about 18 m²/g or less as measured according to ASTM C1274, wherein the at least one layer comprising from 90% to 99.8% by volume of polycrystalline yttrium aluminum garnet (YAG) and from 15 ppm to 500 ppm of zirconium, wherein the at least one layer comprises at least one surface, wherein the at least one surface comprises pores having a pore size not exceeding 5 μm and having a maximum pore size of 1.5 μm for at least 95% of the pores, wherein the at least one surface exhibits an L* value of from 50 to 77, and an a* value of from 6 to 12, wherein the at least one layer has a thickness of from 500 μm to 2 cm, and wherein the values of L* and a* vary no more than 10% across the at least one surface. The following additional steps are optional; annealing the ceramic sintered body by applying heat to raise the temperature of the ceramic sintered body to reach an annealing temperature to form an annealed ceramic sintered body; lowering the temperature of the annealed ceramic sintered body; and machining the ceramic sintered body or the annealed ceramic sintered body to create a ceramic sintered component such as a dielectric window or RF window, a focus ring, a nozzle or a gas injector, a shower head, a gas distribution plate, an etch chamber liner, a plasma source adapter, a gas inlet adapter, a diffuser, an electronic wafer chuck, a chuck, a puck, a mixing manifold, an ion suppressor element, a faceplate, an isolator, a spacer, and/or a protective ring in etch chambers.

The method disclosed herein provides for the preparation of ceramic sintered bodies and components to include yttrium oxide (Y₂O₃), aluminium oxide (Al₂O₃), yttrium aluminum garnet of composition Y₃Al₅O₁₂ (YAG), yttrium aluminum perovskite of composition YAlO₃ (YAP) and yttrium aluminum monoclinic of composition Y₄Al₂O₉ (YAM), and combinations thereof.

In embodiments, the method disclosed herein provides for the preparation of a ceramic sintered body comprising YAG of garnet cubic crystallographic structure in amounts of from 90 to 99.5% by volume of a cubic crystallographic structure, preferably from 90 to 99% by volume of a cubic crystallographic structure, preferably from 95 to 99.5% by volume of a cubic crystallographic structure, preferably from 95 to 99% by volume of a cubic crystallographic structure. In alternate embodiments, a phase of Al₂O₃ in an amount of from 0.1 to 5%, from 0.1 to 3%, from 0.1 to 2%, from 0.1 to 1%, preferably less than 1% by volume may be present in the ceramic sintered body comprising YAG.

Using the materials and methods as disclosed herein, high densities, for example 96%, 98%, 99.5% and greater of theoretical density for phase pure YAG may be achieved for the ceramic sintered body as disclosed without the use of sintering aids. Thus, in embodiments, the ceramic sintered body comprising YAG is substantially free of, or free of, sintering aids (exclusive of zirconium compounds used as dopants as described herein).

In embodiments, the ceramic sintered body comprising from 90% to 99.8% by volume of polycrystalline YAG may comprise excess yttria and/or alumina beyond that of stoichiometric YAG, which may remain from the process or may be intentionally added during powder batching and preparation. The excess yttria and/or alumina are therefore not considered dopants or sintering aids to the extent they may remain in the ceramic sintered body.

In embodiments, the process as disclosed provides for preparation of highly phase pure YAG of greater than 99% by volume cubic crystallographic structure having high (>98%) density, high purity and low porosity. In alternate embodiments, the process as disclosed provides for preparation of highly phase pure YAG of 95% and greater by volume cubic crystallographic structure with a second crystallographic phase of alumina of 5% and less by volume, the sintered body also having high density, high purity and low porosity. In further embodiments, the process as disclosed provides for preparation of mixed phase and/or phase-pure ceramic sintered bodies of yttrium aluminium garnet, Y₃Al₅O₁₂ (YAG), yttrium aluminum perovskite YAlO₃ (YAP) and/or yttrium aluminum monoclinic Y₄Al₂O₉(YAM) and combinations thereof, having high purity, high density and low porosity. The ceramic sintered body as disclosed is particularly suitable for use in a plasma processing apparatus such as a semiconductor manufacturing apparatus. Such parts or members may include windows, nozzles, gas injectors, shower heads, (etch) chamber liners, mixing manifolds, wafer supports, electronic wafer chucks, and various rings such as focus rings and protective rings, among other components.

Step a) of the method disclosed herein comprises combining yttria powder, alumina powder, and a zirconium-containing powder to deliver from 15 to 500 ppm of zirconium to make a first powder mixture. The starting powder materials of aluminium oxide and yttrium oxide for forming a corrosion resistant ceramic sintered body and subsequent component are preferably high purity commercially available powders. However, other oxide powders may be used, for example those produced from chemical synthesis processes and related methods. The d50 is defined as the median and represents the value where half of the population resides above this point, and half resides below this point. Similarly, 90 percent of the distribution lies below the d90, and 10 percent of the population lies below the d10.

The d10 particle size of the yttrium oxide powder used as a starting material according to one embodiment of the present invention is preferably from 1 to 7 μm, preferably from 1 to 6 μm, preferably from 1 to 5 μm, preferably from 2 to 7 μm, preferably from 3 to 7 μm, preferably from 4 to 7 μm, and preferably from 5 to 7 μm.

The d50 particle size of the yttrium oxide powder used as a starting material according to one embodiment of the present invention is preferably 3 to 11 μm, preferably from 3 to 9.5 μm, preferably from 3 to 8.5 μm, preferably from 3 to 7.5 μm, preferably from 4 to 11 μm, preferably from 5 to 11 μm, preferably from 6 to 11 μm, and preferably from 7 to 11 μm.

The d90 particle size of the yttrium oxide powder used as a starting material according to one embodiment of the present invention is preferably from 6 to 20 μm, preferably from 6 to 18 μm, preferably from 6 to 16 μm, preferably from 8 to 20 μm, preferably from 10 to 20 μm, preferably from 15 to 20 μm, preferably from 8 to 18 μm, and preferably from 10 to 18 μm.

The yttrium oxide powder preferably has a specific surface area (SSA) of from 0.75 to 12 m²/g, preferably from 0.75 to 10 m²/g, preferably from 0.75 to 8 m²/g, preferably from 0.75 to 6 m²/g, preferably from 0.75 to 4 m²/g, preferably from 0.75 to 2 m²/g, preferably from 1 to 6 m²/g, preferably from 1 to 4 m²/g, preferably from 2 to 10 m²/g, preferably from 4 to 10 m²/g, preferably from 6 to 10 m²/g, and preferably from 1 to 4 m²/g.

The purity of the yttrium oxide starting material is preferably higher than 99.99%, preferably higher than 99.995%, preferably higher than 99.999%, more preferably higher than 99.9995%, and more preferably higher than 99.9999%. This corresponds to impurity levels of 100 ppm and less, preferably 50 ppm and less, preferably 25 ppm and less, preferably 10 ppm and less, more preferably about 1 ppm, preferably from 1 to 100 ppm, preferably from 1 to 50 ppm, preferably from 1 to 25 ppm, preferably from 1 to 10 ppm, and preferably from 1 to 5 ppm.

The d10 particle size of the aluminum oxide powder used as a starting material according to one embodiment of the present invention is preferably from 0.05 to 4 μm, preferably from 0.05 to 3 μm, preferably from 0.05 to 2 μm, preferably from 0.05 to 1 μm, preferably from 0.05 to 0.75 μm, preferably from 0.05 to 0.5 μm, preferably from 0.2 to 4 μm, preferably from 0.2 to 3 μm, preferably from 0.2 to 2 μm, preferably from 0.2 to 1 μm, preferably from 0.4 to 4 μm, preferably from 0.4 to 3 μm, preferably from 0.4 to 2 μm, preferably from 0.4 to 1 μm, preferably from 0.75 to 2 μm, preferably from 0.75 to 3 μm, preferably from 1 to 3 μm, and preferably from 2 to 3 μm.

The d50 particle size of the aluminum oxide powder used as a starting material according to one embodiment is usually from 0.15 to 8 μm, preferably from 0.15 to 5 μm, preferably from 0.15 to 3 μm, preferably from 0.15 to 1 μm, preferably from 0.15 to 0.5 μm, preferably from 1 to 8 μm, preferably from 1 to 6 μm, preferably from 1 to 4 μm, preferably from 2 to 6 μm, preferably from 3 to 8 μm, preferably from 4 to 8 μm, preferably from 5 to 8 μm, and preferably from 3.5 to 6.5 μm.

The d90 particle size of the aluminum oxide powder used as a starting material according to one embodiment of the present invention is from 0.50 to 75 um, preferably from 0.35 to 10 um, preferably from 0.35 to 5 μm, preferably from 0.35 to 3 μm, preferably from 0.35 to 1 μm, preferably from 0.35 to 0.75 μm, preferably from 3 to 80 um, preferably from 3 to 60 μm, preferably from 3 to 40 μm, preferably from 3 to 20 μm, preferably from 10 to 60 μm, preferably from 10 to 40 μm, preferably from 10 to 30 μm, preferably from 10 to 20 μm, preferably from 30 to 60 μm, preferably from 15 to 60 μm, preferably from 40 to 60 μm, and preferably from 6 to 15 μm.

The aluminum oxide powder usually has a specific surface area of from 3 to 18 m²/g, preferably from 3 to 16 m²/g, preferably from 3 to 14 m²/g, preferably from 3 to 12 m²/g, preferably from 3 to 10 m²/g, preferably from 3 to 6 m²/g, preferably from 6 to 18 m²/g, preferably from 6 to 14 m²/g, preferably from 8 to 18 m²/g, preferably from 10 to 18 m²/g, preferably from 8 to 10 m²/g, preferably from 4 to 9 m²/g, preferably from 5 to 10 m²/g, and preferably from 6 to 8 m²/g.

The purity of the aluminum oxide starting material is typically higher than 99.99%, preferably higher than 99.995%, preferably higher than 99.999%, and preferably higher than 99.9995%, as measured using ICPMS methods. Correspondingly, the impurity content of the alumina powder may be 100 ppm and less, preferably 50 ppm and less, preferably 25 ppm and less preferably 10 ppm and less, and more preferably 5 ppm and less.

In embodiments, the aluminum oxide powder may comprise from 80 to 100% by volume of the alpha alumina crystallographic phase, preferably from 90 to 100% by volume of the alpha alumina crystallographic phase, and preferably from 95 to 100% by volume of the alpha alumina crystallographic phase.

Table 4 lists characteristics of the starting materials as disclosed to form a sintered body comprising YAG. Particle sizes for the starting powders, powder mixtures and calcined powder mixtures were measured using a Horiba model LA-960 Laser Scattering Particle Size Distribution Analyzer capable of measuring particle size from 10 nm to 5 mm. Specific surface area for the starting powders, powder mixtures and calcined powder mixtures was measured using a Horiba BET Surface Area Analyzer model SA-9601 capable of measuring across a specific surface area of 0.01 to 2000 m²/g with an accuracy of 10% and less for most samples.

TABLE 4

| | d10 (um) | d50 (um) | d90 (um) | SSA (m2/g) |
|---|---|---|---|---|
| yttrium oxide | 1 to 7 | 3 to 11 | 6 to 20 | 0.75 to 12 |
| aluminum oxide | 0.05 to 4 | 0.15 to 8 | 0.50 to 75 | 3 to 18 |

To the yttria and alumina powders is added a dopant comprising a zirconium compound, preferably in powder form. Zirconium compounds include, for example, zirconium oxide (zirconia), zirconium chloride, zirconium nitrate, or any other counter ion to zirconium. In preferred embodiments, the zirconium is added as the oxide zirconia and the zirconia may be stabilized with, for example, yttria. The amount of the dopant zirconium compound should be enough to deliver zirconium in an amount of from 15 to 500 ppm, from 15 ppm to 350 ppm, from 15 ppm to 250 ppm, from 15 ppm to 200 ppm, from 15 ppm to 100 ppm, from 15 ppm to 50 ppm, from 50 ppm to 225 ppm, from 50 ppm to 200 ppm, from 50 ppm to 175 ppm, from 50 ppm to 150 ppm, from 50 ppm to 150 ppm, from 50 ppm to 125 ppm, from 50 ppm to 100 ppm, and from 50 ppm to 75 ppm. As a guide, Table 5 provides amounts of zirconia dopant needed to achieve a specific target concentration of zirconium.

TABLE 5

| Target Zr Dopant level | PPM ZrO₂ | Wt % YSZ powder used |
|---|---|---|
| 25 ppm Zr | 100 | 0.0105 |
| 50 ppm Zr | 200 | 0.0210 |
| 100 ppm Zr | 400 | 0.0420 |
| 500 ppm Zr | 2000 | 0.2100 |
| YSZ = 97 mol % ZrO₂ + | | |
| 3 mol % Y₂O₃ | | |

For embodiments, where the zirconium dopant compound is zirconium oxide, the zirconia powder may have a particle size distribution having a d10 of from 0.08 to 0.20 um, a d50 of from 0.3 to 0.7 um and a d90 of from 0.9 to 5 μm. The average particle size of the zirconium oxide powder used as a starting material for the mixture according to one embodiment of the present invention may be from 0.3 to 1 um.

The zirconia powder typically has a specific surface area (SSA) of from 1 to 16 m²/g, preferably from 2 to 14 m²/g, preferably from 4 to 12 m²/g, and more preferably from 5 to 9 m²/g as measured according to ASTM C1274.

The purity of the zirconia powder starting material is preferably higher than 99.8%, preferably higher than 99.9%, preferably higher than 99.95%, preferably higher than 99.975%, preferably higher than 99.99%, and preferably higher than 99.995%. This corresponds to a total impurity content of 2000 um and less, preferably 1000 ppm and less, preferably 500 ppm and less, preferably 250 ppm and less, preferably 100 ppm and less, preferably 50 ppm and less and preferably from 25 to 150 ppm as measured using ICPMS (inductively coupled plasma mass spectrometry) methods as disclosed herein. Zirconia as used in embodiments disclosed herein typically comprises Hf in low amounts of about 2 to 5 wt % as is common in many commercially available zirconia powders.

In other embodiments, it may be preferable that the powder mixture is free of a YAG phase having a specific surface area of about 2 m²/g and greater in order to form at least one first layer of the multilayer sintered ceramic body comprising YAG through the in situ, reactive phase sintering process as disclosed herein. All purity measurements disclosed herein are as measured above the reporting limit for a specific element and were completed using an ICPMS from Agilent, 7900 ICP-MS model G8403, a quadrupole mass spectrometry system. Detection limits using the ICP-MS methods as disclosed herein to identify presence of lighter elements are higher than reporting limits of heavier elements.

In embodiments, the sintered ceramic body comprising from 90% to 99.8% by volume of polycrystalline yttrium aluminum garnet (YAG) and from 15 ppm to 500 ppm of zirconia may be formed from a stoichiometric powder mixture of 37.5 mol % yttrium oxide and 62.5 mol % aluminum oxide. Studies reported in “Mechanisms of nonstoichiometry in Y₃Al₅O₁₂” Patel et al, 2008, Appl. Phys. Lett. 93, 191902 (2008) indicated that the width of the phase domain may have a variance of 0.1 mol % and less. Thus, deviations of 0.1 mol % and less from that of stoichiometric YAG (37.5% alumina/62.5% yttria) may result in formation of phase pure yttrium aluminum oxide garnet. Accordingly, in embodiments a ceramic sintered body comprising yttrium aluminium garnet (YAG) garnet cubic phase (Y₃Al₅O₁₂) in an amount of greater than 99% by volume may be formed from starting powders combined into a powder mixture in a ratio of from 37.4 to 37.6 mol % yttrium oxide and 62.6 and 62.4% mol aluminum oxide. By weight, a powder mixture may be formed from about 42.9 to 43.4% alumina and 57.1 to 56.6% yttria.

Combining the aforementioned starting powders comprising yttrium oxide, aluminium oxide, and zirconium compound dopant to make the first powder mixture may be performed using the powder preparation techniques of wet or dry ball (axially rotating) milling, wet or dry tumble (end over end or vertical) mixing and combinations of these.

Ball milling or end over end tumble mixing under dry conditions may be accomplished using high purity (>99.99%) alumina media in order to preserve the purity of the starting powders during mixing. The high purity alumina media used herein was tested using ICPMS methods and found to have a purity of 99.997%. Media loading for dry ball or tumble mixing may vary between a large dimension (about 30 mm) media element to a media loading of about 50% by powder weight. Dry milling or mixing may be performed for durations of from 12 to 48 hours, preferably from 16 to 48 hours, preferably from 24 to 48 hours, using an RPM of from 50 to 200 RPM, preferably from 75 to 150 RPM, preferably from 100 to 125 RPM.

Wet ball milling or tumble mixing may be performed by suspending the starting powders in various solvents such as ethanol, methanol, and other alcohols, and/or water to form a slurry. The slurry may be formed having a powder loading during milling or mixing of from 5 to 50% by powder weight, preferably from 10 to 40% by powder weight, preferably from 20 to 40% by powder weight. Wet mixing or milling provides for improved dispersion of the powders through increased mobility, resulting in fine scale, uniform mixing before heat treatment or calcination. In specific embodiments, a dispersant may optionally be added to the slurry using any number of commercially available dispersants such as for example poly methyl methacrylate (PMMA) and polyvinyl pyrrolidone (PVP). The dispersant may optionally be added in amounts from zero (no dispersant) to 0.2% by powder weight, preferably from 0 to 0.1% by powder weight. Media loadings may be varied from having no media used during milling, to media at a loading of 50% and greater by powder weight, preferably from 40 to 100% by powder weight, preferably 60 to 100% by powder weight, preferably from 50 to 80% by powder weight. Wet ball milling or tumble mixing may be performed for durations of from 8 to 48 hours, preferably from 12 to 48 hours, preferably from 16 to 48 hours, preferably from 8 to 36 hours, preferably from 8 to 24 hours, preferably from 8 to 12 hours. Ball milling may use an RPM of from 50 to 200 RPM, preferably from 75 to 150 RPM, preferably between 100 and 125 RPM for containers having up to about 200 mm diameter. End over end tumble mixing may be performed at an RPM of from 10 to 30 rpm, preferably about 20.

Jet milling processes as known to those skilled in the art may also be used to thoroughly mix the powders to form a powder, powder mixture or calcined powder mixture having a narrow particle size distribution. Jet milling uses high velocity jets of either inert gases or air to collide particles of the starting powders and/or powder mixtures and/or calcined powder mixtures without the use of milling or mixing media, thus preserving initial purity of the powder to be milled. Starting powders, powder mixtures and/or calcined powder mixtures as disclosed herein may be subjected to jet milling at pressures of about 100 psi, whether separately, or in combination with any, or all of, the as disclosed powder milling/mixing processes as disclosed herein. After jet milling, the powders or powder mixtures may be optionally sieved using any number of meshes which may have openings of for example from 45 to 400 um, and blended, without limitation as to repetition or order.

Use of wet ball milling, tumble mixing and/or jet milling are high energy processes which break down particulates and agglomerates, improves dispersion through increased particle mobility and may provide for fine scale mixing, providing a homogeneous powder mixture prior to calcination. The additional powder preparation procedures of attrition milling, high shear mixing, planetary milling, and other procedures as known to those skilled in the art may also be applied. The slurry may be dried by rotary evaporation methods. In other embodiments, the slurry may be dried using spray drying techniques as known in the art. Before or after drying, the powder mixture may be sieved using a mesh having openings of for example from 35 to 75 um. The aforementioned powder preparation techniques may be used alone or in any combination thereof.

After drying, the surface area of the powder mixture of step a) may be from 2 to 17 m²/g, from 2 to 14 m²/g, from 2 to 12 m²/g, from 2 to 10 m²/g, from 4 to 17 m²/g, from 6 to 17 m²/g, from 8 to 17 m²/g, from 10 to 17 m²/g, from 4 to 12 m²/g, from 4 to 10 m²/g, and from 5 to 8 m²/g.

At this point in the process, if a multilayer sintered ceramic body is to be formed, then a second powder mixture is to be formed. A second powder mixture may comprise, for example, combining alumina powder and zirconia powder wherein the zirconia powder comprises at least one of partially stabilized and stabilized zirconia powder to make a second powder mixture as set forth in U.S. patent application Ser. No. 63/216,356, filed on Jun. 29, 2021, the content of which is incorporated herein by reference.

Step b) of the method disclosed herein comprises heating the first powder mixture (and any additional powder mixtures) to a calcination temperature and maintaining the calcination temperature for a duration to form a first calcined powder mixture (also referred to herein as a “calcined powder mixture”). Calcination as disclosed herein may be performed under ambient pressure in an oxygen containing environment, although other pressures and calcination environments may be used.

Calcination may be performed to remove moisture and ensure the surface condition of the powder mixture is uniform prior to sintering. In certain embodiments, calcination may be performed to reduce surface area. In other embodiments, calcination does not cause a reduction in surface area of the starting powders.

Calcination in accordance with the heat treatment step may be performed at temperatures of from 600° C. to 1100° C., preferably from 600 to 1000° C., preferably from 600 to 900° C., preferably from 700 to 1100° C., preferably from 800 to 1100° C., preferably from 800 to 1000° C., and preferably from 850 to 950° C. Calcination may be performed for durations of from 4 to 12 hours, preferably from 4 to 10 hours, preferably from 4 to 8 hours, preferably from 6 to 12 hours, preferably from 4 to 6 hours in an oxygen containing environment. After calcination, the calcined powder mixture may be sieved through for example a mesh screen having openings of from 45 to 400 μm, and/or tumbled and/or blended according to known methods to form the calcined powder mixture.

The calcined powder mixture to form the YAG phase may have a d10 particle size of preferably from 0.06 to 4 μm, preferably from 0.08 to 4 μm, preferably from 0.1 to 4 μm, preferably from 0.2 to 4 μm, preferably from 0.3 to 4 μm, preferably from 0.4 to 4 μm, preferably from 0.08 to 3 μm, preferably from 0.08 to 2 μm, preferably from 0.08 to 1 μm, preferably from 0.5 to 3 μm, preferably from 1 to 2 μm, and preferably from 1 to 3 μm.

The d50 particle size of the calcined powder mixture may vary from 0.7 to 50 μm, preferably from 1 to 40 μm, preferably from 1 to 30 μm, preferably from 1 to 20 μm, preferably from 1 to 10 μm, preferably from 1 to 5 μm, preferably from 5 to 50 μm, preferably from 10 to 50 μm, preferably from 20 to 50 μm, preferably from 30 to 50 μm, preferably from 3 to 8 μm, preferably from 5 to 10 μm, and preferably from 6 to 15 μm.

The d90 particle size of the calcined powder mixture may be preferably from 10 to 350 μm, preferably from 10 to 300 μm, preferably from 10 to 250 μm, preferably from 10 to 200 μm, preferably from 10 to 175 μm, preferably from 10 to 150 μm, preferably from 10 to 100 μm, preferably from 10 to 75 μm, preferably from 10 to 50 μm, preferably from 10 to 40 μm, preferably from 10 to 30 μm, preferably from 15 to 45 μm, preferably from 20 to 40 μm, preferably from 20 to 350 μm, preferably from 40 to 350 μm, preferably from 60 to 350 μm, preferably from 100 to 350 μm, preferably from 150 to 350 μm, preferably from 200 to 350 μm, preferably from 12 to 330 μm, preferably from 100 to 330 μm, and preferably from 100 to 250 μm.

In certain embodiments, the calcination conditions as disclosed herein may result in formation of one or more of the crystalline phases of YAP, YAM and YAG and combinations thereof, and/or agglomeration of the powder mixture and thus a broad range of particle or agglomerate sizes may result. Thus, in embodiments, the particle size as referred to herein may include a single particle and in other embodiments, the particle size as referred to herein may include an agglomerate comprising more than one particle or an agglomeration of multiple particles which may be measured, using the laser particle size detection methods as disclosed herein, as a single, large particle. Particles comprising either or both of a single particle or an agglomerate of multiple particles may comprise at least one crystalline phase selected from the group consisting of yttrium oxide, aluminum oxide, yttrium aluminium perovskite (YAP), yttrium aluminium monoclinic (YAM), and YAG (garnet) phase, and combinations thereof. In other embodiments, lower temperature calcination conditions as disclosed herein may not affect particle size distributions relative to the starting materials and particle size distributions are in the same range, or similar to, the starting powder materials. Lot to lot variation and management of heat transfer during calcination may also contribute to broadened particle size distributions. The starting powders, powder mixtures and/or the calcined powder mixtures as disclosed herein may be subjected to any one or a combination of the mixing/milling processes as disclosed herein. Thus, a broad range of particle size distributions may result from calcination conditions and processes as disclosed herein.

The calcined powder mixture may have a specific surface area (SSA) of from about 1 m²/g to about 18 m²/g, preferably from about 1 m²/g to about 14 m²/g, preferably from about 1 m²/g to about 10 m²/g, preferably from about 1 m²/g to about 8 m²/g, preferably from about 2 m²/g to about 18 m²/g, preferably from about 2 m²/g to about 14 m²/g, preferably from about 2 m²/g to about 10 m²/g, preferably from about 3 m²/g to about 9 m²/g, preferably from about 3 m²/g to about 6 m²/g as measured according to ASTM C1274.

The calcined powder mixture may have a total impurity content of from 5 to 200 ppm, preferably from 5 to 150 ppm, preferably less than 100 ppm, preferably less than 50 ppm, preferably less than 25 ppm, preferably less than 15 ppm, preferably from 10 to 100 ppm, preferably from 10 to 80 ppm, preferably from 10 to 60 ppm, preferably from 10 to 40 ppm, preferably from 20 to 80 ppm, and preferably from 30 to 60 ppm relative to a mass of the calcined powder mixture.

Table 6 shows ICPMS purity results of a typical calcined powder mixture prior to being formed into a polycrystalline YAG layer according to the present disclosure.

TABLE 6
YAG (Y₃Al₅O₁₂) Calcined Powder Mixture

| | Average | | Average |
|---|---|---|---|
| | Impurity | | Impurity |
| Element | (ppm) | Element | (ppm) |
| Li 6/7 | 0.0197 | Cd 111 | 0.1989 |
| Be 9 | 0.1808 | In 115 | <0.0035 |
| B 11 | <0.0007 | Sn 118 | 0.0798 |
| Na 23 * | 1.8755 | Sb 121 | 0.0297 |
| Mg 24 | <0.7 | Te 126,8,30 | <0.014 |
| Al 27 | N/A | Cs 133 | <0.007 |
| Si 28 | <14 | Ba 137 | <0.056 |
| K 39/41* | <1.4 | La 138/139 | 0.0743 |
| Ca 43/44* | 1.7173 | Ce 140 | 0.0507 |
| Sc 45 | 0.0451 | Pr 141 | 0.0083 |
| Ti 47 | <0.035 | Nd 146 | 0.0264 |
| V 51 | 0.0131 | Sm 147 | 0.0196 |
| Cr 52 | 0.2720 | Eu 153 | 0.0063 |
| Mn 55 | 0.1822 | Gd 157 | 0.0991 |
| Fe 56 | <0.14 | Tb 159 | 0.1991 |
| Co 59 | 0.2041 | Dy 163 | 0.0357 |
| Ni 60 | 0.0978 | Ho 165 | 0.2552 |
| Cu 63 | 0.0660 | Er 166 | 0.1507 |
| Zn 66 | 0.0409 | Tm 169 | 0.1131 |
| Ga 71 | 0.1525 | Yb 171,2,3 | 0.1682 |
| Ge 72 | <0.007 | Lu 175 | 0.0133 |
| As 75 | 0.0306 | Hf 178 | 0.0305 |
| Se 78 | <0.035 | Ta 181 | <0.0035 |
| Rb 85 | 0.0526 | W 182 | <0.007 |
| Sr 84/87/88 | 0.3379 | Re 185 | <0.0035 |
| Y 89 | N/A | Ir 193 | <0.035 |
| | | Pt 195 | <0.056 |
| Nb 93 | <0.007 | Au 197 | 0.0164 |
| Mo 95 | 0.0320 | TI 205 | 0.0430 |
| Ru 101 | <0.007 | Pb 208 | 0.0094 |
| Rh 103 | <0.042 | Bi 209 | 0.0213 |
| Pd 104,8,10 | <0.007 | Th 232 | <0.007 |
| Ag 107/109 | 0.0592 | U 238 | 0.0043 |

*N/A represents elements present in starting powders forming the powder mixtures

In one embodiment, the sintered ceramic body comprises polycrystalline yttrium aluminum garnet having impurities of 50 ppm or less of trace metals Na, Fe, and Mg as determined by ICPMS. In another embodiment, the sintered ceramic body comprises polycrystalline yttrium aluminum garnet having impurities of 5 ppm or less of trace metals Na, Fe, and Mg as determined by ICPMS. In yet another embodiment, the sintered ceramic body comprises polycrystalline yttrium aluminum garnet having a purity of 50 ppm or less of trace elements Li, Na, Mg, K, Ca, B, P, Fe, Cu, Cr, Zn, In, Sn, and Sb (total) as determined by ICPMS.

Step c) of the method disclosed herein comprises disposing the calcined powder mixture inside a volume defined by a tool set of a sintering apparatus to form at least one layer of the first calcined powder mixture and creating vacuum conditions inside the volume. A spark plasma sintering (SPS) apparatus used in the process as disclosed herein comprises at least a graphite die which is usually a cylindrical graphite die. In the graphite die, the first calcined powder mixture is disposed between two graphite punches. In embodiments where a multilayer sintered ceramic body is formed, calcined powder mixtures are sequentially added to correspond with the desired layers of sintered material.

In preferred embodiments, the SPS tool comprises a die comprising a sidewall comprising an inner wall and an outer wall, wherein the inner wall has a diameter that defines an inner volume capable of receiving at least one ceramic powder; and an upper punch and a lower punch operably coupled with the die, wherein each of the upper punch and the lower punch have an outer wall defining a diameter that is less than the diameter of the inner wall of the die thereby defining a gap between each of the upper punch and the lower punch and the inner wall of the die when at least one of the upper punch and the lower punch are moved within the inner volume of the die, wherein the gap is from 10 μm to 100 μm wide. In some embodiments, the gap is from 10 μm to 70 μm wide. Preferably, the die and punches are made of graphite. Such SPS tool is disclosed in U.S. provisional patent application Ser. No. 63/087,204, filed Oct. 3, 2020, which is herein incorporated by reference.

In embodiments, one or more (for multilayer embodiments) calcined powder mixtures may be disposed within the graphite die (sequentially for multilayer embodiments). Vacuum conditions as known to those skilled in the art are established within the powder between the punches surrounded by the die. Typical vacuum conditions include pressures of 10⁻² to 10⁻³ torr. The vacuum is applied primarily to remove air to protect the graphite from burning and to remove a majority of the air from the powder mixtures. In multilayer embodiments, the order of powder mixture disposition may be reversed or repeated as necessary to achieve the desired structure of the multilayer sintered ceramic body and component formed therefrom. In such embodiments, layers of the first and second calcined powder mixtures are contiguous as disposed within the graphite die during sintering, and thereafter sinter to form first and second contiguous layers.

Step d) of the method disclosed herein comprises applying pressure to the at least one layer the calcined powder mixture while heating to a sintering temperature and performing sintering to form a sintered ceramic body comprising the at least one layer comprising from 90% to 99.8% by volume of polycrystalline yttrium aluminum garnet (YAG) and from 15 ppm to 500 ppm of zirconium, and step e) comprises lowering the temperature of the sintered ceramic body by, for example, removing the heat source to the sintering apparatus to cool the ceramic sintered body.

Pressure may be applied to the calcined powder mixture disposed between the graphite punches and increased to a pressure of from 5 MPa to 100 MPa, preferably from 5 MPa to 60 MPa, preferably from 5 MPa to 40 MPa, preferably from 5 MPa to 20 MPa, preferably from 5 MPa to 15 MPa, preferably from 10 MPa to 60 MPa, preferably from 10 MPa to 40 MPa, preferably from 10 MPa to 30 MPa, preferably from 10 MPa to 20 MPa, preferably from 13 MPa to 18 MPa, preferably from 15 MPa to 60 MPa preferably from 15 MPa to 40 MPa, preferably from 15 MPa to 30 MPa, and preferably from 20 to 40 MPa. The pressure is applied axially on the powder mixture in the die.

In preferred embodiments, the powder mixture is heated directly by the punches and die of the sintering apparatus. The die may be comprised of an electrically conductive material such as graphite, which facilitates resistive/joule heating. The temperature of the sintering apparatus according to the present disclosure is measured usually within the graphite die of the apparatus. Thereby, it is preferred that the temperature is measured as close as possible to the calcined powder mixture being processed so that the indicated temperatures are indeed realized within the calcined powder mixture to be sintered.

The application of heat to the calcined powder mixture and/or layered powder mixtures provided in the die facilitates sintering temperatures of from 1000 to 1700° C., preferably from 1200 to 1700° C., preferably from 1400 to 1700° C., preferably from 1500 to 1700° C., more preferably from 1600 to 1700° C., preferably from 1200 to 1600° C., preferably from 1200 to 1400° C., preferably from 1400 to 1600° C., preferably from 1500 to 1600° C. Sintering may typically be achieved with an isothermal time of from 0.5 to 180 minutes, preferably from 0.5 to 120 minutes, preferably from 0.5 to 100 minutes, preferably from 0.5 to 80 minutes, preferably from 0.5 to 60 minutes, preferably from 0.5 to 40 minutes, preferably from 0.5 to 20 minutes, preferably from 0.5 to 10 minutes, preferably from 0.5 to 5 minutes, preferably from 5 to 120 minutes, preferably from 10 to 120 minutes preferably from 20 to 120 minutes preferably from 40 to 120 minutes preferably from 60 to 120 minutes, preferably from 80 to 100 minutes, preferably from 100 to 120 minutes preferably from 30 to 60 minutes, preferably from 15 to 45 minutes. In certain embodiments, sintering may be achieved with an isothermal time of zero and upon reaching the sintering temperature, a cooling rate as disclosed herein is initiated. During sintering, a volume reduction typically occurs such that the ceramic sintered body may comprise a volume that is about one third that of the volume of the starting powder mixture when disposed in the tool set of the sintering apparatus. The polycrystalline YAG is preferably formed in situ by reactive sintering during the sintering step by way of the combined properties of particle size distribution, purity and/or surface area of the powder mixtures as disclosed herein.

The order of application of pressure and temperature in one embodiment may vary according to the present disclosure, which means that it is possible to apply at first the indicated pressure and thereafter to apply heat to achieve the desired temperature. Moreover, in other embodiments it is also possible to apply at first the indicated heat to achieve the desired temperature and thereafter the indicated pressure. In a third embodiment according to the present disclosure, the temperature and the pressure may be applied simultaneously to the calcined powder mixture to be sintered and raised until the indicated values are reached.

Inductive or radiant heating methods may also be used for heating the sintering apparatus and indirectly heating the calcined powder mixture in the tool set.

In contrast to other sintering techniques, sintering aids are not required (although they may be used if desired). Additionally, a high purity starting powder is desirable for optimal etch performance. The lack of sintering aids and the use of high purity starting materials, from 99.99% to about 99.9999% purity as disclosed herein, enables the fabrication of a high purity, high density/low porosity ceramic sintered body which provides improved etch resistance for use as a ceramic sintered component in semiconductor etch chambers.

In one embodiment of the present invention, process step d) may further comprise a pre-sintering step with a specific heating ramp of from 0.1° C./min to 100° C./min, from 0.1° C./min to 50° C./min, from 0.1° C./min to 25° C./min, preferably 0.5° C./min to 50° C./min, preferably 0.5 to 25° C./min, preferably 0.5 to 10° C./min, preferably from 0.5° C./min to 5° C./min, preferably 0.75 to 25° C./min, preferably 1 to 10° C./min, preferably 1 to 5° C./min until a specific pre-sintering time is reached.

In a further embodiment of the present invention, process step d) may further comprise a pre-sintering step with a specific pressure ramp of from 0.50 MPa/min to 30 MPa/min, preferably 0.75 MPa/min to 20 MPa/min, more preferably 1 to 10 MPa/min until a specific pre-sintering time is reached.

At the end of process step d), the method further comprise step e) lowering the temperature of the sintered ceramic body in accordance with a natural cooling of the process chamber (unforced cooling) under vacuum conditions as known to those skilled in the art. In a further embodiment in accordance with process step e), the ceramic sintered body may be cooled under convection with inert gas, for example, at 1 bar of argon or nitrogen. Other gas pressures of greater than or less than 1 bar may also be used. In a further embodiment, the ceramic sintered body is cooled under forced convective conditions in an oxygen environment. To initiate the cooling step, the power applied to the sintering apparatus is removed and the pressure applied to the ceramic sintered body is removed at the end of the sintering step d and thereafter cooling occurs in accordance with step e). Cooling rates for the ceramic sintered body as disclosed herein may be from 0.5 to 20° C./minute from 1 to 10° C./minute, preferably from 1 to 8° C./minute, preferably from 1 to 5° C./minute, preferably from 2 to 10° C./minute, preferably from 2 to 8° C./minute, preferably from 2 to 5° C./minute. At the end of process step d), the sintered ceramic body is typically very dark in color, i.e., it will have an L* value<30.

Optionally, but preferably, the method as disclosed herein comprises the step of annealing the sintered ceramic body (or component formed therefrom) by applying heat to raise the temperature of the sintered ceramic body to reach an annealing temperature, performing annealing; and lowering the temperature of the annealed sintered ceramic body (or component formed therefrom). In the optional annealing step in accordance with embodiments as disclosed herein, the multilayer sintered ceramic body may be subjected to temperatures of from about 900 to about 1800° C., preferably from about 1250 to about 1700° C., preferably from about 1300 to about 1650° C., and preferably from about 1400 to about 1600° C.

In embodiments, the optional annealing of the sintered ceramic body may be carried out at a heating and/or a cooling rate of from 0.5° C./min to 50° C./min, preferably from 0.5° C./min to 25° C./min, more preferably from 0.5° C./min to 10° C./min, and more preferably from 0.5° C./min to 5° C./min, more preferably from 1° C./min to 50° C./min, more preferably from 3° C./min to 50° C./min, more preferably from 5° C./min to 50° C./min, more preferably from 25° C./min to 50° C./min, preferably from 1° C./min to 10° C./min, preferably from 2° C./min to 10° C./min, and preferably from 2° C./min to 5° C./min.

Durations of the optional annealing step may be from 1 to 24 hours, preferably from 1 to 18 hours, preferably from 1 to 16 hours, preferably from 1 to 8 hours, preferably from 4 to 24 hours, preferably from 8 to 24 hours, preferably from 12 to 24 hours, preferably from 4 to 12 hours, and preferably from 6 to 10 hours.

In an embodiment, optional annealing in accordance with this disclosure may be performed after the sintering process and within the sintering apparatus. The optional process of annealing may preferably be performed under oxidizing conditions such as forced convection or in air. Annealing leads to a refinement of the chemical and physical properties of the sintered ceramic body or component fabricated therefrom through reduction of oxygen vacancies for stoichiometric correction and reduced stress in the sintered body or component. The optional process step of annealing the sintered corrosion resistant component is carried out in an oxidizing atmosphere, whereby the annealing process may provide increased albedo, improved mechanical handling and reduced porosity. After the optional process step of annealing the multilayer sintered ceramic body is performed, the temperature of the sintered, and in some instances annealed, multilayer sintered ceramic body is decreased to an ambient temperature by removal of the heat source. At the end of process step e), the annealed sintered ceramic body is typically lighter in color due to oxidation, i.e., it will have an L* value of between 70 and 85. An example is shown in Table 7 wherein color measurements were made on an annealed YAG layer of a 22-inch circular part (2,452 cm²) made according to the method disclosed herein. Five measurements were made across the part and the average and standard deviation for each color variable are shown in Table 7.

TABLE 7
Color after annealing

| | L* | a* | b* |
|---|---|---|---|
| 1 | 72.16 | −0.66 | −0.3 |
| 2 | 69.79 | −0.65 | −0.4 |
| 3 | 75.14 | −0.59 | −0.23 |
| 4 | 71.81 | −0.65 | −0.44 |
| 5 | 74.76 | −0.67 | −0.66 |
| Avg. | 72.73 | −0.644 | −0.314 |
| Std. Dev. | 1.987153 | 0.028 | 0.296351 |

Step f) of the method disclosed herein is exposing the sintered ceramic body to UV radiation for a time period of from 1 to 400 minutes. The purpose of the UV exposing step is to activate the doped zirconium to impart a red color to the sintered ceramic body. The length of time of UV radiation exposure should be determined by the uniformity and intensity of the red color imparted to the sintered ceramic body. Total exposure time will depend on the intensity of the UV lamp used to radiate the sintered ceramic body.

In preferred embodiments, the UV radiation is delivered by a UV lamp such as, for example, a Heraeus Noblelight Hammer Mark II LH10 Lamp System using an H⁺ bulb and an R500 reflector at a distance of 3 inches from the sintered ceramic body for an exposure time period of about 6 hours.

At the end of process step f), the sintered ceramic body comprises at least one layer comprising from 90% to 99.8% by volume of polycrystalline yttrium aluminum garnet (YAG) and from 15 ppm to 500 ppm of zirconium, wherein the at least one layer comprises at least one surface, wherein the at least one surface comprises pores having a pore size not exceeding 5 μm and having a maximum pore size of 1.5 μm for at least 95% of the pores, wherein the at least one surface exhibits an L* value of from 50 to 77 and preferably from 50 to 60, an a* value of from 6 to 12 and a b* value of from 3 to 6, wherein the at least one layer has a thickness of from 500 μm to 2 cm, and wherein the values of L* and a* vary no more than 10% across the at least one surface.

The process described above is suitable to produce sintered ceramic bodies as disclosed herein having a greatest dimension of, for example, from 100 to about 625 mm, preferably from 100 to 622 mm, preferably from 200 to about 625 mm, preferably from 300 to about 625 mm, preferably from 400 to about 625 mm, preferably from 500 to about 625 mm, preferably from 300 to 622 mm, preferably from 400 to 622 mm, and preferably from 500 to 622 mm. Despite the large size, the sintered ceramic bodies produced according to the method disclosed herein have uniform densities as much as 99.5% of the theoretical value of YAG. The sintered ceramic bodies are formed, for example, in a disc shape having a diameter as greatest dimension. The process as disclosed provides for rapid powder consolidation and densification, retaining a maximum grain size of about 10 um and less in the sintered ceramic body, and achieving high densities and low porosities within the at least one first layer across the greatest dimension. This combination of fine grain size, high density, and CTE matching provides for a high strength sintered ceramic body of large dimension suitable for machining, handling and use as a component in semiconductor plasma processing chambers.

Step j) of the method as disclosed herein comprises machining the sintered ceramic body (or the annealed sintered ceramic body) to create a sintered ceramic component in the shape of a window, a lid, a dielectric window, an R F window, a ring, a focus ring, a process ring, a deposition ring, a nozzle, an injector, a gas injector, a shower head, a gas distribution plate, a diffuser, an ion suppressor element, a chuck, an electrostatic wafer chuck (ESC), and a puck. Machining, drilling, boring, grinding, lapping, polishing, and the like as known to those skilled in the art may be performed as necessary to form the sintered ceramic body into a predetermined shape of a component for use in plasma processing chambers. Use of the powder mixtures in the compositional ranges as disclosed herein may provide a sintered ceramic body having improved machinability through use of CTE matched layers, thereby reducing stress during the machining step of the method as disclosed.

The methods and compositions disclosed herein will be illustrated in more detail with reference to the following Examples, but it should be understood that the it is not deemed to be limited thereto.

### EXAMPLES

The following examples are included to more clearly demonstrate the overall nature of the disclosure. These examples are exemplary, not restrictive, of the disclosure.

Measurements for all examples were performed using the equipment and methods as disclosed. Purity measurements were performed using an ICP-MS from Agilent 7900 ICP-MS model G8403. Specific surface areas (SSA) for powders and powder mixtures were measured using a Horiba BET Surface Area Analyzer model SA-9601. Specific surface area measurements were performed according to ASTM C1274. Particle sizes were measured using a Horiba model LA-960 Laser Scattering Particle Size Distribution Analyzer capable of measuring particle size from 10 nm to 5 mm. For all examples, and in view of the need to minimize contamination, a total concentration of undesirable elements in raw materials used is at most 1 atomic %.

The sintered ceramic bodies made in the Examples below were round and had a diameter of 620 mm.

### Example 1 YAG—No Dopant

A powder of yttria (purity 99.9984%, impurities about 16 ppm relative to mass) having a specific surface area of from 4.5 to 6 m²/g, a d10 particle size of from 2.0 to 3.5 μm, a d50 particle size of from 4.0 to 6.5 μm and a d90 particle size of from 6.5 to 10 μm, and a powder of alumina (purity about 99.9995%, impurities about 5 ppm relative to mass) having a specific surface area of from 6 to 8 m²/g, a d10 particle size of from 0.075 to 0.2 μm, a d50 particle size of from 2.5 to 5.5 μm and a d90 particle size of from 15 to 22 μm were combined in a molar ratio to form a powder mixture which upon sintering reacts to forms a ceramic sintered body comprising the cubic, yttrium aluminum garnet (YAG) phase. High purity alumina media (≥99.9% as measured by ICPMS) was added at about 60% loading relative to powder weight, and ethanol was added in an amount of about 35% by combined weight of ethanol and powder to form a slurry. Tumble mixing or end-over-end mixing as known to those skilled in the art was performed for a duration of 20 hours and thereafter the ethanol was extracted from the powder mixture using rotary evaporation according to known methods. Upon calcination at 1050° C. for 6 hours in air, the calcined powder mixture was measured to have a specific surface area of from 4 to 6 m²/g. The powders, powder mixture and/or calcined powder mixture may be sieved using aperture sizes of from 45 to 400 um, calcined, blended and/or milled at various process steps according to methods known to those skilled in the art. Purity was measured using ICPMS methods as disclosed herein, and a total impurity content of the calcined powder mixture of about 5 ppm relative to a total mass of the oxides calculated from all constituents was measured, corresponding to a purity of about 99.9995%. Purity limits and impurity contents for the starting powders of yttria and alumina, as well as the calcined powder mixtures as disclosed herein do not include Si. The detection limit using ICPMS methods to measure purity as disclosed herein for Si is about 14 ppm, thus the starting powders of yttria and alumina as well as the calcined powder mixtures may comprise Si in the form of silica at a detection level of about 14 ppm. The calcined powder mixture was disposed inside a volume defined by a tool set of a sintering apparatus as disclosed herein, and vacuum conditions of from 10⁻² to 10⁻³ torr were created inside the volume. A pressure of 5 MPa was applied, and the calcined powder mixture inside the volume was heated from ambient temperature at about 10° C./minute to 800° C., and thereafter pressure was ramped at a rate of about 0.4 to about 0.6 MPa/minute and the temperature ramp was continued as previous to reach the sintering conditions of 1600° C. and 15 MPa for 60 minutes to form a polycrystalline YAG sintered ceramic body in a disc shape having 150 mm greatest dimension. Density measurements were performed in accordance with ASTM B962-17 on the as-sintered and the annealed sample. Densities of 4.549 g/cc were averaged across 5 measurements. This corresponds to 99.854% respectively, of the theoretical density for YAG (reported herein as 4.556 g/cc) and corresponding volumetric porosity of 0.146%, as calculated from density measurements. The sample as processed has the appearance of a dark grey ceramic with slight transparency when ground thin for light penetration. The sample is then oxidized at 1400° C. using a heating rate of 1-5° C./minute to 1400° C. for 8 hours resulting in a translucent white material.

### Example 2 Zr-Doped

A powder of yttria (purity 99.9984%, impurities about 16 ppm relative to mass) having a specific surface area of from 4.5 to 6 m²/g, a d10 particle size of from 2.0 to 3.5 μm, a d50 particle size of from 4.0 to 6.5 μm and a d90 particle size of from 6.5 to 10 μm, and a powder of alumina (purity about 99.9995%, impurities about 5 ppm relative to mass) having a specific surface area of from 6 to 8 m²/g, a d10 particle size of from 0.075 to 0.2 μm, a d50 particle size of from 2.5 to 5.5 μm and a d90 particle size of from 15 to 22 μm were combined in a molar ratio to form a powder mixture which upon sintering reacts to forms a ceramic sintered body comprising the cubic, yttrium aluminum garnet (YAG) phase. High purity alumina media (≥99.9% as measured by ICPMS) was added at about 60% loading relative to powder weight, and ethanol was added in an amount of about 35% by combined weight of ethanol and powder to form a slurry. In addition, yttria-stabilized zirconia powder was placed into the mixture at the appropriate dopant level (purity about 99.9954%, impurities about 46 ppm relative to mass, and discounting typical yttrium and hafnium impurities as typical with stabilized zirconia) having a specific surface area of from 6.0 to 8.0 μm m²/g, a d10 particle size of from 0.075 to 0.2 μm, a d50 particle size of from 0.25 μm to 0.45 μm, and a d90 particle size 1.0 to 2.0 μm. Tumble mixing or end-over-end mixing as known to those skilled in the art was performed for a duration of 20 hours and thereafter the ethanol was extracted from the powder mixture using rotary evaporation according to known methods. Upon calcination at 1050° C. for 6 hours in air, the calcined powder mixture was measured to have a specific surface area of from 4 to 6 m²/g. The powders, powder mixture and/or calcined powder mixture may be sieved using aperture sizes of from 45 to 400 um, calcined, blended and/or milled at various process steps according to methods known to those skilled in the art. Purity was measured using ICPMS methods as disclosed herein, and a total impurity content of the calcined powder mixture of about 5 ppm relative to a total mass of the oxides calculated from all constituents was measured, corresponding to a purity of about 99.9995%. Purity limits and impurity contents for the starting powders of yttria and alumina, as well as the calcined powder mixtures as disclosed herein do not include Si. The detection limit using ICPMS methods to measure purity as disclosed herein for Si is about 14 ppm, thus the starting powders of yttria and alumina as well as the calcined powder mixtures may comprise Si in the form of silica at a detection level of about 14 ppm. The calcined powder mixture was disposed inside a volume defined by a tool set of an SPS sintering apparatus as disclosed herein, and vacuum conditions of from 10⁻² to 10⁻³ torr were created inside the volume. A pressure of 5 MPa was applied, and the calcined powder mixture inside the volume was heated from ambient temperature at about 10° C./minute to 800° C., and thereafter pressure was ramped at a rate of about 0.4 to about 0.6 MPa/minute and the temperature ramp was continued as previous to reach the sintering conditions of 1600° C. and 15 MPa for 60 minutes to form a polycrystalline YAG sintered ceramic body in a disc shape having 150 mm greatest dimension. Density measurements were performed in accordance with ASTM B962-17 on the as-sintered and the annealed sample. Densities of 4.549 g/cc were averaged across 5 measurements. This corresponds to 99.854% respectively, of the theoretical density for YAG (reported herein as 4.556 g/cc) and corresponding volumetric porosity of 0.146%, as calculated from density measurements. The sample as processed has the appearance of a dark red/black ceramic with slight transparency when ground thin for light penetration. The sample is then oxidized at 1400° C. using a heating rate of 1-5° C./minute to 1400° C. for 8 hours resulting in a translucent white material.

For samples with and without doped zirconium, the UV radiation step was performed with a UV lamp (Heraeus Noblelight Hammer Mark II LH10 Lamp System using an H⁺ bulb and an R500 reflector) at a distance of 3 inches from the sintered ceramic body for an exposure time period of about 6 hours. Results are shown in Table 8. Sample 144 was prepared according to Example 1 above and Samples 135, 149, and 142 were prepared according to Example 2, however, with varying amounts of doped zirconium. Sample 144 (0 ppm Zr) had a slight color change response where it picked up a slight pink color compared to the strong red coloration of the 135 sample.

TABLE 8
Results

| | PPM | CeLAB color Pre-UV | | | CeLAB color Post-UV | | |
|---|---|---|---|---|---|---|---|
| Sample | Zr | L* | a* | b* | L* | a* | b* |
| 144 | 0 | 77.63 | −0.88 | −1.08 | 66.81 | 5.62 | 3.24 |
| 135 | 50 | 80.19 | −0.63 | −1.72 | 54.87 | 11.56 | 4.84 |
| 149 | 100 | 84.21 | −0.27 | −0.83 | 69.25 | 10.12 | 5.16 |
| 142 | 500 | 84.96 | −0.25 | 0.28 | 75.19 | 7.36 | 4.51 |

### Example 3: Porosity Measurements

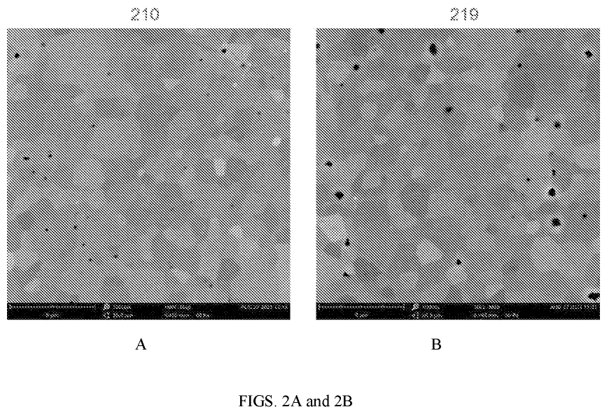

Two sintered ceramic bodies (labelled 210 and 219) were made according to the method of Example 2 (doped with 50 ppm of zirconium). The surface was polished and the level of porosity was measured across sample surfaces through use of SEM images (FIGS. 2A and 2B) obtained from a Phenom XL scanning electron microscope at 10,000× magnification. Images were imported into ImageJ Software for analysis. ImageJ has been developed at the National Institute of Health (NIH), USA, and is a Java-based public domain image processing and analysis program for image processing of scientific multi-dimensional images.

Pore size were measured across 7 SEM images using ImageJ software methods as disclosed herein. Sample 210 exhibited a maximum pore size of 1.01 μm and Sample 219 exhibited a maximum pore size of 0.94 μm.

A number of embodiments have been described as disclosed herein. Nevertheless, it will be understood that various modifications may be made without departing from the spirit and scope of the embodiments as disclosed herein. Accordingly, other embodiments are within the scope of the following claims.

1. A sintered ceramic body comprising:
at least one layer comprising from 90% to 99.8% by volume of polycrystalline yttrium aluminum garnet (YAG) and from 15 ppm to 500 ppm of zirconium, wherein the at least one layer comprises at least one surface, wherein the at least one surface comprises pores having a pore size not exceeding 5 μm, wherein the at least one surface exhibits an L* value of from 50 to 77, and an a* value of from 6 to 12, wherein the at least one layer has a thickness of from 500 μm to 2 cm, and wherein the values of L* and 21* vary no more than 10% across the at least one surface.

2. The sintered ceramic body of claim 1 wherein the at least one layer has a b* value of from 3 to 6.

3. The sintered ceramic body of claim 2 wherein the b* value varies no more than 15% across the at least one surface.

4-6. (canceled)

7. The sintered ceramic body as in claim 1, wherein the value of L* varies no more than 3% and the value of a* varies no more than 9% across the at least one surface.

8. The sintered ceramic body as in claim 1, wherein the polycrystalline yttrium aluminum garnet comprises pores having a pore size not exceeding 1.75 μm for at least 97% or more of all pores and wherein the polycrystalline yttrium aluminum garnet has a volumetric porosity of from 0.1 to 3%.

9-12. (canceled)

13. The sintered ceramic body as in claim 1, wherein the polycrystalline yttrium aluminum garnet is present in an amount of from 93 to 99.8% by volume excluding any Al₂O₃ or zirconium present.

14. The sintered ceramic body as in claim 1, wherein the polycrystalline ceramic body has impurities of 50 ppm or less of trace metals Na, Fe, and Mg as determined by ICPMS.

15. The sintered ceramic body as in claim 1, wherein the pores occupy less than 0.2% of the surface area.

16. (canceled)

17. The sintered ceramic body as in claim 1, and having a greatest dimension of from 100 mm to 625 mm.

18. (canceled)

19. The sintered ceramic body as in claim 17 having a density variance of from 0.2 to less than 5% as measured across the greatest dimension.

20-21. (canceled)

22. A method for preparing a sintered ceramic body comprising the steps of:
a. combining yttria powder, alumina powder, and a zirconium-containing powder to deliver from 15 to 500 ppm of zirconium to make a first powder mixture;
b. calcining the first powder mixture by applying heat to raise the temperature of the first powder mixture to a calcination temperature and maintaining the calcination temperature to perform calcination to form a first calcined powder mixture;
c. disposing the first calcined powder mixture inside a volume defined by a tool set of a sintering apparatus to form at least one layer of the first calcined powder mixture and creating vacuum conditions inside the volume;
d. applying pressure to the at least one layer of the first calcined powder mixture while heating to a sintering temperature and performing sintering to form a sintered ceramic body comprising the at least one layer comprising from 90% to 99.8% by volume of polycrystalline yttrium aluminum garnet (YAG) and from 15 ppm to 500 ppm of zirconium;
e. lowering the temperature of the sintered ceramic body; and
f. exposing the sintered ceramic body to UV radiation for a time period of from 1 to 400 minutes,
wherein the first calcined powder mixture has a total impurity content of 150 ppm or less,
wherein the yttria and alumina powders in step a) each have a specific surface area of about 18 m²/g or less as measured according to ASTM C1274,
wherein sintered ceramic layer comprises at least one layer comprising from 90% to 99.8% by volume of polycrystalline yttrium aluminum garnet (YAG) and from 15 ppm to 500 ppm of zirconium,
wherein the at least one layer comprises at least one surface,
wherein the at least one surface comprises pores having a pore size not exceeding 5 μm and having a maximum pore size of 1.5 μm for at least 95% of the pores,
wherein the at least one surface exhibits an L* value of from 50 to 77, and an a* value of from 6 to 12,
wherein the at least one layer has a thickness of from 500 μm to 2 cm, and
wherein the values of L* and a* vary no more than 10% across the at least one surface.

23. The method of claim 22 further comprising the following steps:
g. annealing the sintered ceramic body by applying heat to raise the temperature of the sintered ceramic body to reach an annealing temperature and performing annealing;
h. lowering the temperature of the annealed multilayer sintered ceramic body; and
i. optionally machining the sintered ceramic body or the annealed sintered ceramic body to create a sintered ceramic component in the shape of a dielectric window, an RF window, a focus ring, a process ring, a deposition ring, a nozzle or a gas injector, a shower head, a gas distribution plate, an etch chamber liner, a plasma source adapter, a gas inlet adapter, a diffuser, an electrostatic wafer chuck (ESC), a chuck, a puck, an ion suppressor element, a faceplate, an isolator, a spacer, and/or a protective ring in plasma processing chambers.

24. The method of claim 22 wherein the tool set comprises a graphite die having a volume, an inner wall, a first and second openings, and first and second punches operatively coupled with the die, wherein each of the first and second punches have an outer wall defining a diameter that is less than a diameter of the inner wall of the die thereby creating a gap between each of the first and second punches and the inner wall of the die when at least one of the first and second punches moves within the volume of the die.

25. The method of claim 24 wherein the gap is a distance of from 10 to 100 μm between the inner wall of the die and the outer wall of each of the first and second punches.

26. The method according to claim 22 wherein the sintering temperature is from 1000 to 1500° C.

27-38. (canceled)
